(19) United States
(12) Patent Application Publication
(10) Pub. No.: US 2018/0151814 A1
(43) Pub. Date: May 31, 2018

(54) Light-Emitting Element, Light-Emitting Device, Electronic Device, Display Device, and Lighting Device

(71) Applicant: Semiconductor Energy Laboratory Co., Ltd., Kanagawa-ken (JP)

(72) Inventors: Tomoya Hirose, Atsugi (JP); Satoshi Seo, Sagamihara (JP); Tetsuo Tsutsui, Kasuga (JP)

(73) Assignee: Semiconductor Energy Laboratory Co., Ltd., Kanagawa-ken (JP)

(21) Appl. No.: 15/824,328

(22) Filed: Nov. 28, 2017

(30) Foreign Application Priority Data
Nov. 30, 2016 (JP) 2016-233190
Jan. 24, 2017 (JP) 2017-010585

(51) Int. Cl. H01L 51/00; H01L 51/50; C09K 11/06

(52) U.S. Cl. CPC H01L 51/0077; H01L 51/508; H01L 51/0037; H01L 51/0035; C09K 11/06; H01L 27/3244; H01L 51/0058; H01L 51/5092; H01L 51/5012; H01L 51/0005; H01L 51/0072

(57) ABSTRACT

A novel light-emitting element is provided. A light-emitting element with high emission efficiency is provided. A light-emitting element with high color purity is provided. The light-emitting element includes an anode, a cathode, and a layer including the light-emitting substance between the anode and the cathode. The layer including the light-emitting substance includes a light-emitting layer, a first electron-transport layer, and a second electron-transport layer. The light-emitting layer and the first electron-transport layer are in contact with each other. The first electron-transport layer and the second electron-transport layer are in contact with each other. The first electron-transport layer and the second electron-transport layer are positioned between the light-emitting layer and the cathode. The light-emitting layer includes a metal-halide perovskite material represented by General Formula (SA)MX₃, General Formula (LA)₂(SA)ₙ₋₁MₙX₃ₙ₊₁, or General Formula (PA)(SA)ₙ₋₁MₙX₃ₙ₊₁. The first electron-transport layer includes a first electron-transport material, and the second electron-transport layer includes a second electron-transport material.

### BACKGROUND OF THE INVENTION

### 1. Field of the Invention

One embodiment of the present invention relates to a light-emitting element, a display module, a lighting module, a display device, a light-emitting device, an electronic device, and a lighting device. Note that one embodiment of the present invention is not limited to the above technical field. The technical field of one embodiment of the invention disclosed in this specification and the like relates to an object, a method, or a manufacturing method. Furthermore, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a storage device, an imaging device, a method for driving any of them, and a method for manufacturing any of them.

### 2. Description of the Related Art

With the development of the display technology, the required level of performance is increasing day by day. The sRGB standard and the NTSC standard are conventionally well-known indicators for showing the reproducible color gamut of a display. Moreover, the BT.2020 standard, which covers a wider color gamut, has been proposed recently.

The BT.2020 standard can express almost all object colors; however, it is difficult under the present conditions to achieve it simply by using a broad emission spectrum of an organic compound as it is. Therefore, an attempt to meet the BT.2020 standard by increasing the color purity with the use of a cavity structure or the like has been made.

As another approach for meeting the BT.2020 standard, a material that originally has a narrow half width of an emission spectrum is used. Specifically, a quantum dot (QD), which is a tiny particle of several nanometers of a compound semiconductor, attracts attention as a substance for high color purity because a QD has discrete electron states and the discreteness limits the phase relaxation, narrowing the emission spectrum. The QD is expected as a light-emitting material which achieves the chromaticity of the BT.2020 standard.

A QD is made up of approximately 1×10³ to 1×10⁶ atoms and confines electrons, holes, or excitons, which produces discrete energy states and causes an energy shift depending on the size of QD. This means that QDs made of the same substance emit light with different wavelengths depending on their size; thus, the wavelength of light can be easily adjusted by changing the size of a QD.

In addition, a QD is said to have a theoretical internal quantum efficiency of approximately 100%, which far exceeds that of a fluorescent organic compound (25%) and is comparable to that of a phosphorescent organic compound.

However, if the particle size varies, the half width of the emission spectrum of the QD is broadened. Thus, the color purity which enables the satisfaction of the above-mentioned standard has not been achieved under the present conditions. Furthermore, the valence band (VB) maximum of the QD is positioned much deeper than the highest occupied molecular orbital (HOMO) level of a light-emitting material that is normally used in an organic EL element. Therefore, injection of holes to the light-emitting layer is difficult with the same structure for the normal organic EL element, and sufficiently high efficiency has not been achieved yet.

Patent Document 1 discloses a light-emitting element in which a tungsten oxide is used in a hole-injection layer and a quantum dot is used as a light-emitting substance.

### REFERENCE

### Patent Document

[Patent Document 1] PCT International Publication No. 2012/013272

### SUMMARY OF THE INVENTION

An object of one embodiment of the present invention is to provide a highly efficient light-emitting element having a sharp spectrum.

An object of one embodiment of the present invention is to provide a novel light-emitting element. Another object of one embodiment of the present invention is to provide a highly efficient light-emitting element. Another object of one embodiment of the present invention is to provide a light-emitting element with high color purity.

Another object of one embodiment of the present invention is to provide a light-emitting device, an electronic device, and a display device each with low power consumption. Another object of one embodiment of the present invention is to provide a light-emitting device, an electronic device, and a display device each with favorable display quality.

It is only necessary that at least one of the above-described objects be achieved in the present invention.

One embodiment of the present invention is a light-emitting element which includes an anode, a cathode, and a layer including a light-emitting substance between the anode and the cathode. In this embodiment, the layer including the light-emitting substance includes a light-emitting layer, a first electron-transport layer, and a second electron-transport layer. The light-emitting layer and the first electron-transport layer are in contact with each other. The first electron-transport layer and the second electron-transport layer are in contact with each other. The first electron-transport layer and the second electron-transport layer are positioned between the light-emitting layer and the cathode. The light-emitting layer includes a metal-halide perovskite material. The first electron-transport layer includes a first electron-transport material. The second electron-transport layer includes a second electron-transport material.

Another embodiment of the present invention is a light-emitting element which includes an anode, a cathode, and a layer including the light-emitting substance between the anode and the cathode. In this embodiment, the layer including the light-emitting substance includes a light-emitting layer, a first electron-transport layer, and a second electron-transport layer. The light-emitting layer and the first electron-transport layer are in contact with each other. The first electron-transport layer and the second electron-transport layer are in contact with each other. The first electron-transport layer and the second electron-transport layer are positioned between the light-emitting layer and the cathode. The light-emitting layer includes a metal-halide perovskite material represented by General Formula (SA)MX₃, General Formula (LA)₂(SA)ₙ₋₁MₙX₃ₙ₊₁, or General Formula (PA)(SA)ₙ₋₁MₙX₃ₙ₊₁. The first electron-transport layer includes a first electron-transport material. The second electron-transport layer includes a second electron-transport material.

Note that M represents a divalent metal ion, X represents a halogen ion, and n represents an integer of 1 to 10. Furthermore, LA is an ammonium ion represented by R¹—NH₃⁺. In the above formula, R¹ represents any one or more of an alkyl group having 2 to 20 carbon atoms, an aryl group having 6 to 20 carbon atoms, and a heteroaryl group having 4 to 20 carbon atoms. In the case where R¹ represents two or more of the alkyl group having 2 to 20 carbon atoms, the aryl group having 6 to 20 carbon atoms, and the heteroaryl group having 4 to 20 carbon atoms, a plurality of groups of the same kind or different kinds may be used as R¹. Furthermore, PA represents NH₃⁺—R²—NH₃⁺, NH₃⁺—R³—R⁴—R⁵—NH₃⁺, or a part or whole of a polymer including ammonium cations, and the valence of PA is +2. In addition, R² represents a single bond or an alkylene group having 1 to 12 carbon atoms, R³ and R⁵ independently represent a single bond or an alkylene group having 1 to 12 carbon atoms, R⁴ represents one or two of a cyclohexylene group and an arylene group having 6 to 14 carbon atoms. In the case where R⁴ represents two of the cyclohexylene group and the arylene group having 6 to 14 carbon atoms, a plurality of groups of the same kind or different kinds may be used as R⁴. Furthermore, SA represents a monovalent metal ion or an ammonium ion represented by R⁶—NH₃⁴ in which R⁶ is an alkyl group having 1 to 6 carbon atoms.

Another structure of the present invention is the light-emitting element having the above-described structure, in which LA is any of substances represented by General Formulae (A-1) to (A-11) and General Formulae (B-1) to (B-6), and PA is any of substances represented by General Formulae (C-1), (C-2), and (D) or branched polyethyleneimine including ammonium cations.

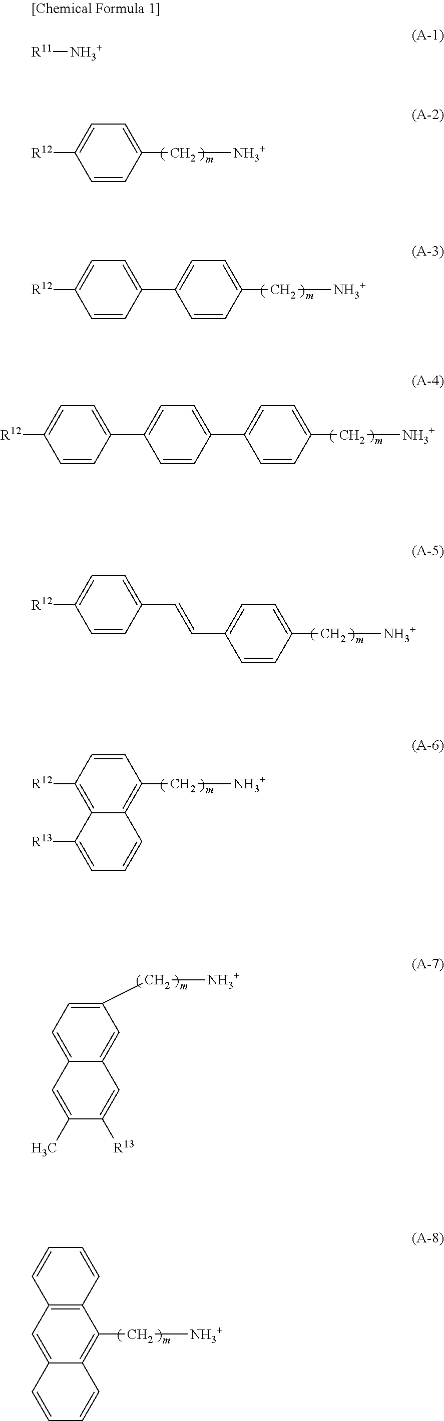

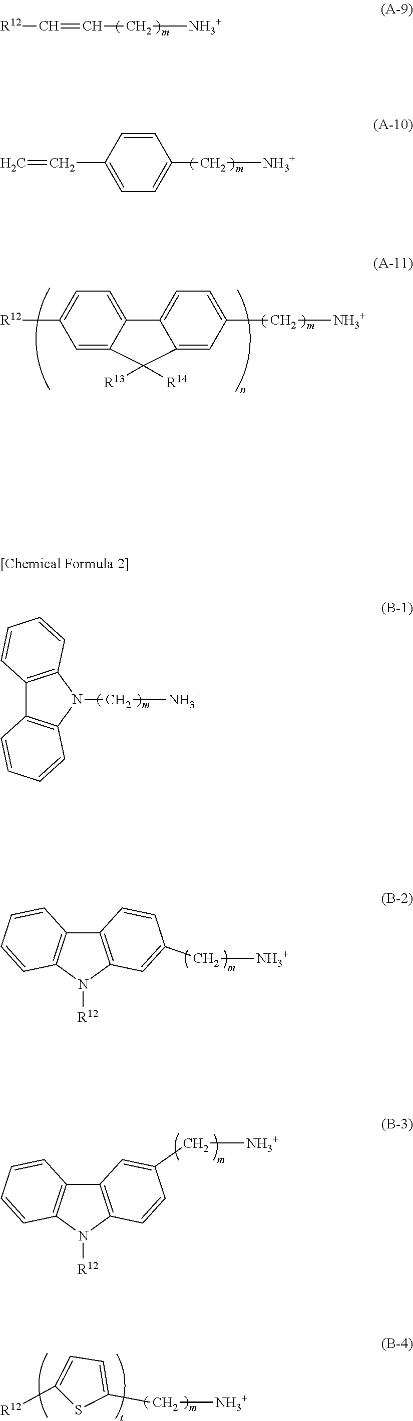

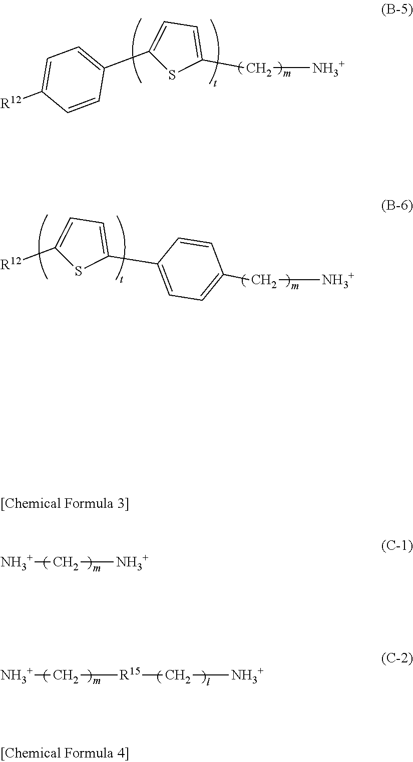

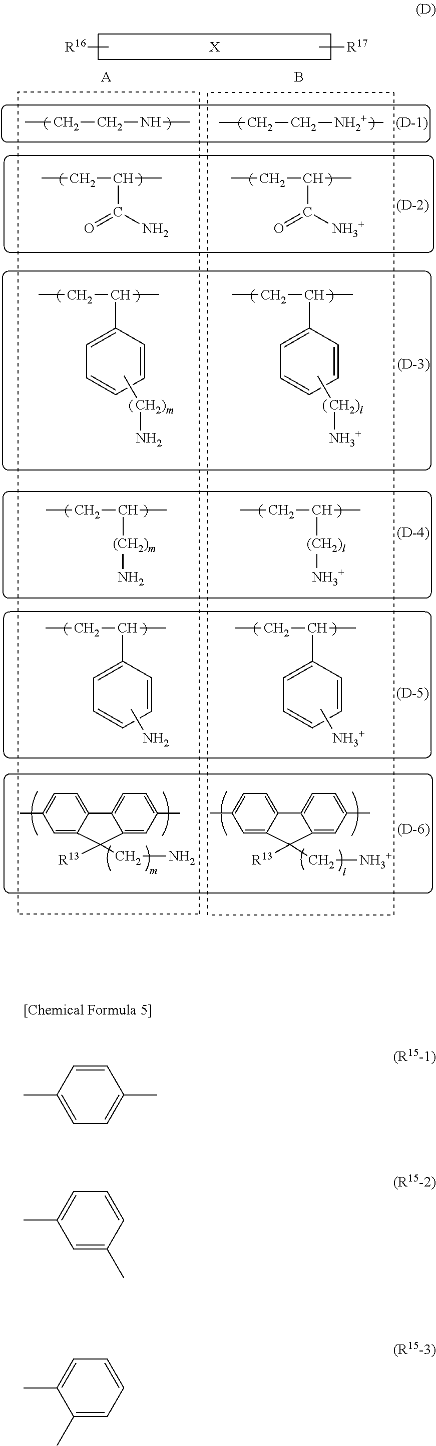

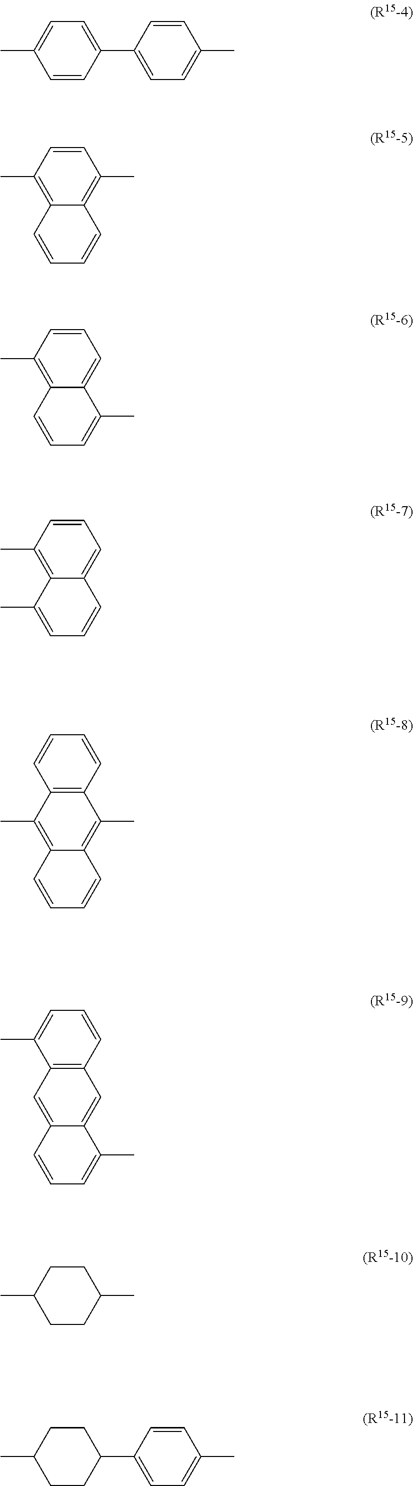

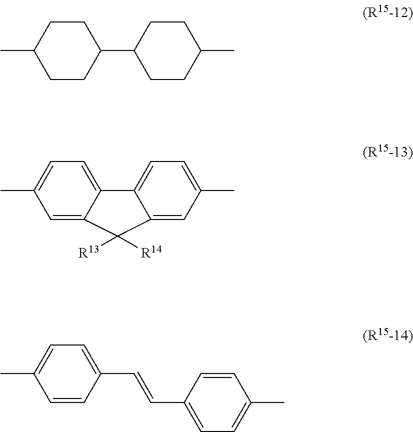

In the above general formulae, R¹¹ represents an alkyl group having 2 to 18 carbon atoms, R¹², R¹³, and R¹⁴ represent hydrogen or an alkyl group having 1 to 18 carbon atoms, and R¹⁵ represents a substance represented by any of Structural or General Formulae (R¹⁵-1) to (R¹⁵-14). Furthermore, R¹⁶ and R¹⁷ independently represent hydrogen or an alkyl group having 1 to 6 carbon atoms. In addition, X represents a combination of a monomer unit A and a monomer unit B represented by any of General Formulae (D-1) to (D-6), and has a structure including u monomer units A and v monomer units B. Note that the arrangement order of the monomer units A and B is not limited. Furthermore, m and/are independently an integer of 0 to 12, and t is an integer of 1 to 18. In addition, u is an integer of 0 to 17, v is an integer of 1 to 18, and u+v is an integer of 1 to 18.

Another structure of the present invention is the light-emitting element having the above-described structure, which further includes an electron-injection buffer layer between the second electron-transport layer and the cathode.

Another structure of the present invention is the light-emitting element having the above-described structure, in which the electron-injection buffer layer includes an alkali metal or an alkaline earth metal.

Another structure of the present invention is the light-emitting element having the above-described structure, in which the second electron-transport material interacts with the alkali metal or the alkaline earth metal to form a state which facilitates electron injection from the cathode to the layer including the light-emitting substance.

Another structure of the present invention is the light-emitting element having the above-described structure, in which the first electron-transport material is a substance which suppresses diffusion of the alkali metal or the alkaline earth metal to the light-emitting layer.

Another structure of the present invention is the light-emitting element having the above-described structure, in which the second electron-transport material is a substance having a six-membered heteroaromatic ring including nitrogen.

Another structure of the present invention is the light-emitting element having the above-described structure, in which the second electron-transport material is a substance having a 2,2′-bipyridine skeleton.

Another structure of the present invention is the light-emitting element having the above-described structure, in which the second electron-transport material is a phenanthroline derivative.

Another structure of the present invention is the light-emitting element having the above-described structure, in which the first electron-transport material has a higher electron mobility than the second electron-transport material.

Another structure of the present invention is the light-emitting element having the above-described structure, in which the first electron-transport material has a fluorescence quantum yield of 0.5 or more.

Another structure of the present invention is the light-emitting element having the above-described structure, in which the first electron-transport material is a substance having a condensed aromatic hydrocarbon ring.

Another structure of the present invention is the light-emitting element having the above-described structure, in which the first electron-transport material is an anthracene derivative.

Another structure of the present invention is the light-emitting element having the above-described structure, in which the metal-halide perovskite material is a particle including a longest part being 1 μm or less.

Another structure of the present invention is the light-emitting element having the above-described structure, in which the metal-halide perovskite material has a layered structure in which a perovskite layer and an organic layer are stacked.

Another structure of the present invention is the light-emitting element having the above-described structure, in which the external quantum efficiency is 5% or more.

Another structure of the present invention is a light-emitting device which includes the light-emitting element having the above-described structure, a substrate, and a transistor.

Another structure of the present invention is an electronic device which includes the light-emitting device having the above-described structure; and a sensor, an operation button, a speaker, or a microphone.

Another structure of the present invention is a lighting device which includes the light-emitting device having the above-described structure; and a housing.

Note that the light-emitting device in this specification includes, in its category, an image display device that uses a light-emitting element. The light-emitting device may include a module in which a light-emitting element is provided with a connector such as an anisotropic conductive film or a tape carrier package (TCP), a module in which a printed wiring board is provided at the end of a TCP, and a module in which an integrated circuit (IC) is directly mounted on a light-emitting element by a chip on glass (COG) method. Furthermore, the light-emitting device may be included in lighting equipment or the like.

In one embodiment of the present invention, a novel light-emitting element can be provided. In another embodiment of the present invention, a light-emitting element with a long lifetime can be provided. In another object of one embodiment of the present invention, a light-emitting element with high emission efficiency can be provided.

In another embodiment of the present invention, a highly reliable light-emitting device, a highly reliable electronic device, and a highly reliable display device can be provided. In another embodiment of the present invention, a light-emitting device, an electronic device, and a display device each with low power consumption can be provided.

Note that the description of these effects does not preclude the existence of other effects. One embodiment of the present invention does not necessarily have all the effects listed above. Other effects will be apparent from and can be derived from the description of the specification, the drawings, the claims, and the like.

### BRIEF DESCRIPTION OF THE DRAWINGS

In the accompanying drawings:

FIGS. 1A to 1C are schematic views each illustrating a light-emitting element;

FIGS. 2A to 2D illustrate an example of a method for manufacturing a light-emitting element;

FIG. 3 illustrates an example of a method for manufacturing a light-emitting element;

FIGS. 4A and 4B are conceptual diagrams of an active-matrix light-emitting device;

FIGS. 5A and 5B are each a conceptual diagram of an active-matrix light-emitting device;

FIG. 6 is a conceptual diagram of an active-matrix light-emitting device;

FIGS. 7A and 7B are each a conceptual diagram of a passive-matrix light-emitting device;

FIGS. 8A and 8B illustrate a lighting device;

FIGS. 9A, 9B1, 9B2, 9C, and 9D each illustrate an electronic device;

FIG. 10 illustrates a light source device;

FIG. 11 illustrates a lighting device;

FIG. 12 illustrates a lighting device;

FIG. 13 illustrates car-mounted display devices and lighting devices;

FIGS. 14A to 14C illustrate an electronic device;

FIGS. 15A to 15C illustrate an electronic device;

FIG. 16 illustrates a structure example of a display panel;

FIG. 17 illustrates a structure example of a display panel;

FIG. 18 shows emission spectra of Light-emitting Elements 1 to 3;

FIG. 19 shows chromaticity coordinates of Light-emitting Elements 1 to 3; and

FIG. 20 shows external quantum efficiency-luminance characteristics of Light-emitting Elements 1 to 3.

### DETAILED DESCRIPTION OF THE INVENTION

Embodiments of the present invention will be described below with reference to the drawings. It will be readily appreciated by those skilled in the art that modes and details of the present invention can be modified in various ways without departing from the spirit and scope of the present invention. Thus, the present invention should not be construed as being limited to the description in the following embodiments.

### Embodiment 1

A metal-halide perovskite material is a composite material of an organic material and an inorganic material or a material formed of only an inorganic material, and has some interesting properties such as light emission by excitons or high carrier mobility. The metal-halide perovskite material has a superstructure in which inorganic layers (also referred to as perovskite layers) and organic layers are alternately stacked, which forms a quantum well structure. Therefore, the metal-halide perovskite material exhibits particularly high exciton binding energy, so that excitons can exist stably. Furthermore, the metal-halide perovskite material has a narrow half width and exhibits light emission by exciton with a small Stokes shift; thus, usage in a light-emitting element is expected. Moreover, a quantum dot of the metal-halide perovskite material is also known as a substance that exhibits favorable color-purity light emission with an extremely narrow half width.

In addition, because the metal-halide perovskite material has an excellent self-assembly property, a thin film sample or a single crystal sample can be easily formed with a wet process by only applying a solution of the raw material. A favorable light-emitting layer can also be formed by using a quantum dot of the metal-halide perovskite material with a size of several tens of nanometers to several hundreds of nanometers.

Moreover, a light-emitting element in which the metal-halide perovskite material is used as a light-emitting substance can be formed to be light and thin, can be easily formed as a planar light source, can be used to form a minute pixel, and can be bent, for example, like an organic EL element containing an organic compound as a light-emitting substance (hereinafter, such an element is also referred to as an OLED element). In addition, a light-emitting element using the metal-halide perovskite material as a light-emitting substance can be comparable to or advantageous over an OLED element in color purity, lifetime, efficiency, emission wavelength selection facility, and the like.

Like an OLED element, a light-emitting element using the metal-halide perovskite material as a light-emitting substance can emit light when a current is fed through an EL layer that is provided between an anode and a cathode and includes a light-emitting layer containing the metal-halide perovskite material as a light-emitting substance. The EL layer may include functional layers such as a hole injection/transport layer, an electron injection/transport layer, and a buffer layer and other functional layers, in addition to the light-emitting layer. The hole injection/transport layer and the electron injection/transport layer each have functions of transporting carriers injected from an electrode and injecting the carriers into the light-emitting layer.

Because the VB maximum and the conduction band minimum of the metal-halide perovskite material are positioned close to the HOMO level and the lowest unoccupied molecular orbital (LUMO) level of an organic compound which is a light-emitting substance for an OLED element, materials similar to those for the OLED element can be used as the above-described functional layers.

However, a light-emitting element using the metal-halide perovskite material as a light-emitting substance cannot emit light with favorable efficiency conventionally. According to the consideration by the present inventors, possible reasons for the insufficient efficiency are difficulty of electron injection, severely poor carrier balance due to a high hole-transport property of the metal-halide perovskite material itself, and quenching by a sensitive reaction with an alkali metal or an alkaline earth metal that is used for hole injection, for example.

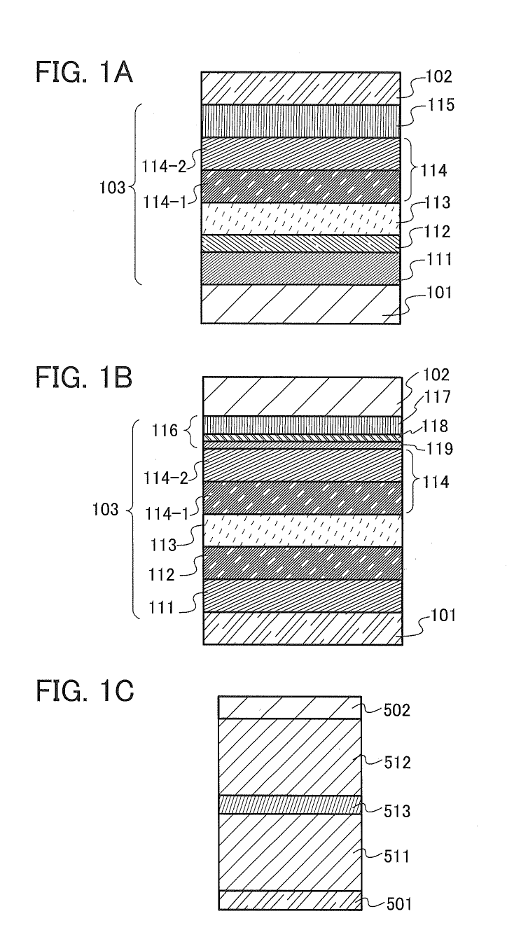

A light-emitting element of this embodiment includes a layer 103 containing a light-emitting substance which includes a light-emitting layer 113, a first electron-transport layer 114-1, and a second electron-transport layer 114-2, between an anode 101 and a cathode 102, as illustrated in FIGS. 1A and 1B. The light-emitting layer 113 contains the metal-halide perovskite material, the first electron-transport layer 114-1 contains a first electron-transport material, and the second electron-transport layer 114-2 contains a second electron-transport material. The first electron-transport material and the second electron-transport material are different materials.

In addition to these layers, a hole-injection layer 111, a hole-transport layer 112, an electron-injection buffer layer 115, and other layers may be included in the layer 103 containing a light-emitting substance. Note that the first electron-transport layer 114-1 is formed in contact with the light-emitting layer 113, the second electron-transport layer 114-2 is formed in contact with the first electron-transport layer 114-1, and the second electron-transport layer 114-2 is formed between the first electron-transport layer 114-1 and the cathode 102.

The metal-halide perovskite material contained in the light-emitting layer 113 can be represented by any of General Formulae (G1) to (G3).

(SA)MX₃ (G1)

(LA)₂(SA)ₙ₋₁MₙX₃ₙ₊₁ (G2)

(PA)(SA)ₙ₋₁MₙX₃ₙ₊₁ (G3)

In the above general formulae, M represents a divalent metal ion, and X represents a halogen ion.

Specific examples of the divalent metal ion are divalent cations of lead, tin, or the like.

Specific examples of the halogen ion are anions of chlorine, bromine, iodine, fluorine, or the like.

Note that n represents an integer of 1 to 10. In the case where n is larger than 10 in General Formula (G2) or (G3), the metal-halide perovskite material has properties close to those of the metal-halide perovskite material represented by General Formula (G1).

Moreover, LA is an ammonium ion represented by R¹—NH₃⁺.

In the ammonium ion represented by R¹—NH₃⁺, R¹ represents any one of an alkyl group having 2 to 20 carbon atoms, an aryl group having 6 to 20 carbon atoms, and a heteroaryl group having 4 to 20 carbon atoms. Alternatively, R¹ represents a group in which an alkyl group having 2 to 20 carbon atoms, an aryl group having 6 to 20 carbon atoms, or a heteroaryl group having 4 to 20 carbon atoms is combined with an alkylene group having 1 to 12 carbon atoms, a vinylene group, an arylene group having 6 to 13 carbon atoms, and a heteroarylene group having 6 to 13 carbon atoms. In the latter case, a plurality of alkylene groups, vinylene groups, arylene groups, and heteroarylene groups may be coupled, and a plurality of groups of the same kind may be included. In the case where a plurality of alkylene groups, vinylene groups, arylene groups, and heteroarylene groups are coupled, the total number of alkylene groups, vinylene groups, arylene groups, and heteroarylene groups is preferably smaller than or equal to 35.

Furthermore, SA represents a monovalent metal ion or an ammonium ion represented by R⁶—NH₃⁺, in which R⁶ is an alkyl group having 1 to 6 carbon atoms.

Moreover, PA represents NH₃⁺—R²—NH₃⁺, NH₃⁺—R³—R⁴—R⁵—NH₃⁺, or a part or whole of branched polyethyleneimine including ammonium cations, and the valence of PA is +2. Note that charges are roughly in balance in the general formula.

Here, charges of the metal-halide perovskite material are not necessarily in balance strictly in every portion of the material in the above formula as long as the neutrality is roughly maintained in the material as a whole. In some cases, other ions such as a free ammonium ion, a free halogen ion, or an impurity ion exist locally in the material and neutralize the charges. In addition, in some cases, the neutrality is not maintained locally also at a surface of a particle or a film, a crystal grain boundary, or the like; thus, the neutrality is not necessarily maintained in every location.

Note that in the above formula (G2), (LA) can be any of substances represented by General Formulae (A-1) to (A-11) and General Formulae (B-1) to (B-6) below, for example.

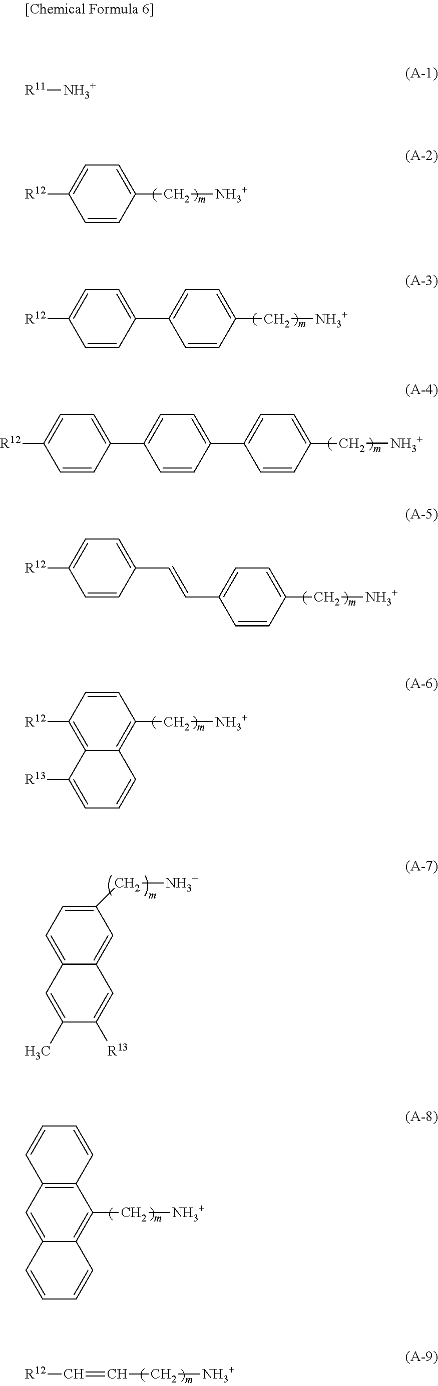

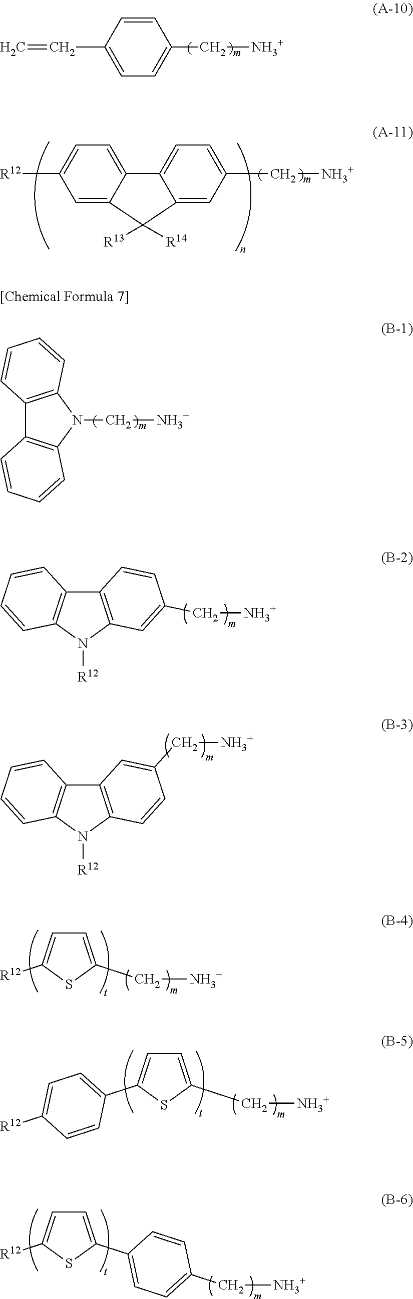

Furthermore, (PA) in General Formula (G3) is typically any of substances represented by General Formulae (C-1), (C-2), and (D) below or a part or whole of branched polyethyleneimine including ammonium cations, and the valence of (PA) is +2. These polymers may neutralize charges over a plurality of unit cells. Alternatively, one charge of each of two different polymer molecules may neutralize charges of one unit cell.

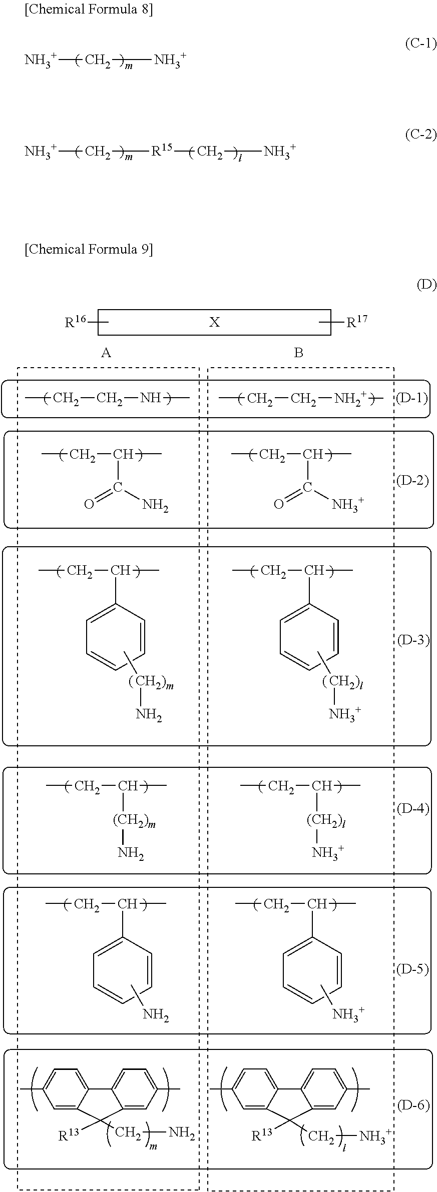

Note that in the above general formulae, R¹¹ represents an alkyl group having 2 to 18 carbon atoms, R¹², R¹³, and R¹⁴ represent hydrogen or an alkyl group having 1 to 18 carbon atoms, and R¹⁵ represents a substance represented by any of Structural or General Formulae (R¹⁵-1) to (R¹⁵-14) below. Furthermore, R¹⁶ and R¹⁷ independently represent hydrogen or an alkyl group having 1 to 6 carbon atoms. In addition, X represents a combination of a monomer unit A and a monomer unit B represented by any of General Formulae (D-1) to (D-6), and has a structure including u monomer units A and v monomer units B. Note that the arrangement order of the monomer units A and B is not limited. Furthermore, m and l are independently an integer of 0 to 12, and t is an integer of 1 to 18. In addition, u is an integer of 0 to 17, v is an integer of 1 to 18, and u+v is an integer of 1 to 18.

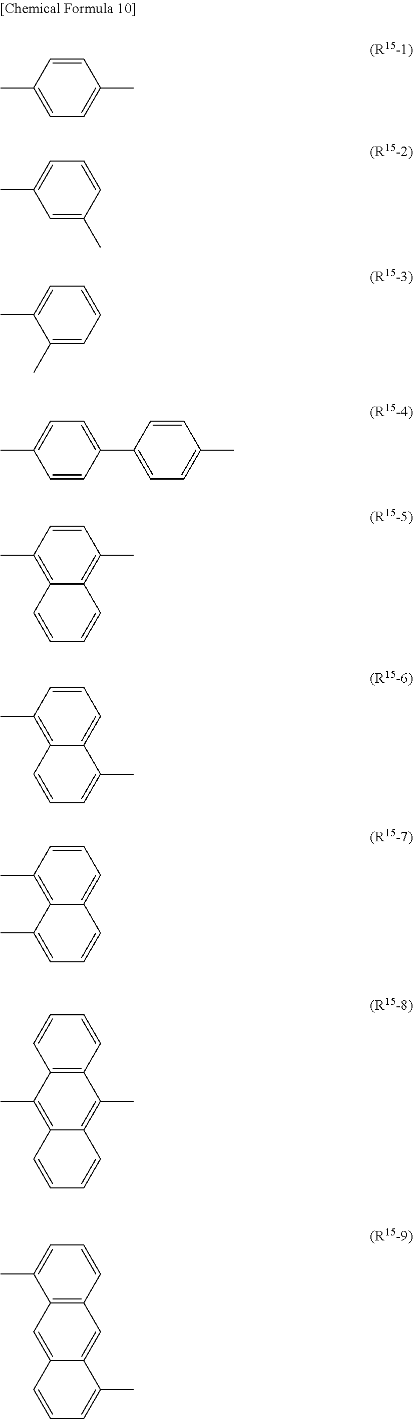

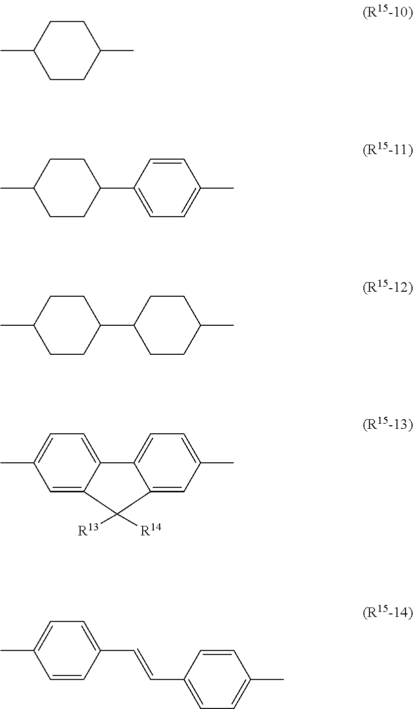

The substances that can be used as (LA) and (PA) may be, but not limited to, the above-described examples.

The metal-halide perovskite material having a three-dimensional structure including the composition (SA)MX₃ represented by General Formula (G1) includes regular octahedron structures each of which has a metal atom M at the center and six halogen atoms at the vertexes. Such regular octahedron structures are three-dimensionally arranged by sharing the halogen atoms of the vertexes, so that a skeleton is formed. This octahedral structure unit including a halogen atom at each vertex is referred to as a perovskite unit. There are a zero-dimensional structure body in which a perovskite unit exists in isolation, a linear structure body in which perovskite units are one-dimensionally coupled with a halogen atom at the vertex, a sheet-shaped structure body in which perovskite units are two-dimensionally coupled, and a structure body in which perovskite units are three-dimensionally coupled. Furthermore, there are also a complicated two-dimensional structure body in which a plurality of sheet-shaped structure bodies having two-dimensionally coupled perovskite units are stacked, and more complicated structure bodies. All of these structure bodies having a perovskite unit are collectively defined as a metal-halide perovskite material.

In the three-dimensional structure body in which halogen atoms of all the perovskite units are coupled three-dimensionally, each perovskite unit is negatively charged and the negatively-charged perovskite unit is monovalent. In addition, a monovalent SA cation located at a gap between the coupled perovskite units neutralizes the negative charges. In the other structure bodies, some halogen atoms forming the octahedrons do not share the vertexes of the octahedrons, and thus the negatively-charged perovskite units are not monovalent. Accordingly, the percentage of contained cations which cancel out the negative charges of the perovskite units changes depending on how the perovskite units are coupled. In the three-dimensional perovskite, the size of cations is limited by the size of the gap between the coupled perovskite skeletons. In the other structure bodies, the size and shape of cations dominate the coupling form of the perovskite units reversely, which increases the material design flexibility. Accordingly, a variety of perovskite structure bodies can be devised by molecular design of the size and shape of cation species which are an organic amine.

General Formulae (G2) and (G3) represent special two-dimensional perovskite materials among the above-described metal-halide perovskite materials and have a structure in which a plurality of layers of the two-dimensional structure bodies (also referred to as perovskite layers or inorganic layers) are stacked and segregated by a variety of sizes and shapes of organic ions (corresponding to (LA) and (PA) in the above formulae).

The thickness of the light-emitting layer 113 is 3 nm to 1000 nm, preferably 10 nm to 100 nm, and the metal-halide perovskite material content of the light-emitting layer is 1 vol % to 100 vol %. Note that the light-emitting layer is preferably formed of only the metal-halide perovskite material. The light-emitting layer including the metal-halide perovskite material can typically be formed by a wet process (e.g., a spin coating method, a casting method, a die coating method, a blade coating method, a roll coating method, an inkjet method, a printing method, a spray coating method, a curtain coating method, or a Langmuir-Blodgett method) or a vacuum evaporation method.

Specifically, in the case of using a wet process, a solution obtained by dissolving a metal halide corresponding to M and X in the above general formulae and organic ammonium corresponding to (SA), (LA), or (PA) in a liquid medium is applied and dried, or quantum dots of the metal-halide perovskite material are dispersed in a liquid medium and then applied and dried. Thus, the light-emitting layer 113 can be formed. In the case of using an evaporation method, a method of vapor depositing the metal-halide perovskite material by a vacuum evaporation method, a method of co-evaporating a metal halide and organic ammonium, or the like can be employed. Alternatively, other methods may be employed for the film formation.

To form a light-emitting layer in which quantum dots of the metal-halide perovskite material are dispersed as a light-emitting material in a host material, the quantum dots may be dispersed in the host material, or the host material and the quantum dots may be dissolved or dispersed in an appropriate liquid medium, and then a wet process (e.g., a spin coating method, a casting method, a die coating method, a blade coating method, a roll coating method, an ink-jet method, a printing method, a spray coating method, a curtain coating method, or a Langmuir-Blodgett method) or co-evaporation using a vacuum evaporation method may be employed. For a light-emitting layer containing the metal-halide perovskite material, a vacuum evaporation method, as well as the wet process, can be suitably employed.

An example of the liquid medium used for the wet process is an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like.

Quantum dots of the metal-halide perovskite material can have a variety of shapes such as a rod shape, a plate shape, and a spherical shape, in addition to a cube shape. The size is smaller than or equal to 1 μm, preferably smaller than or equal to 500 nm.

The first electron-transport material contained in the first electron-transport layer 114-1 is preferably a substance with a favorable electron-transport property. This is to adjust the carrier balance because the metal-halide perovskite material has a favorable hole-transport property. If the carrier balance is lost owing to the high hole-transport property of the metal-halide perovskite material, reductions in emission efficiency and lifetime might occur owing to formation of a light-emitting region leaning on one side or passage of holes to the electron-transport layer. Specifically, a substance having an electron mobility of higher than or equal to 10⁻⁶ cm²/Vs is preferable.

The metal-halide perovskite material sensitively reacts with an alkali metal or an alkaline earth metal, such as lithium, so that quenching is caused. An alkali metal or an alkaline earth metal is often used as a material of the electron-injection buffer layer 115 to assist electron injection from the cathode 102. For this reason, the first electron-transport material is preferably a compound having a function of suppressing diffusion of an alkali metal or an alkaline earth metal, in particular, lithium. As such a material, an anthracene derivative is particularly preferable. An anthracene derivative effectively suppresses diffusion of an alkali metal or an alkaline earth metal and has a favorable electron-transport property.

As the first electron-transport material, metal complexes such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), and the like can be given, for example. Furthermore, a heterocyclic compound having a polyazole skeleton can also be used, and for example, an oxadiazole derivative such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), or 9-[4-(5-phenyl-1,3,4-oxadiazol-2-yl)phenyl]-9H-carbazole (abbreviation: CO11); a triazole derivative such as 3-(4-biphenylyl)-4-phenyl-5-(4-tert-butylphenyl)-1,2,4-triazole (abbreviation: TAZ); and a benzimidazole derivative such as 2,2′,2″-(1,3,5-benzenetriyl)tris(1-phenyl-1H-benzimidazole) (abbreviation: TPBI) or 2-[3-(dibenzothiophen-4-yl)phenyl]-1-phenyl-1H-benzimidazole (abbreviation: mDBTBIm-II) can be given. Furthermore, a heterocyclic compound having a diazine skeleton such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); a heterocyclic compound having a triazine skeleton such as 2,4,6-tris(biphenyl-3-yl)-1,3,5-triazine (abbreviation: T2T), 2,4,6-tris[3′-(pyridin-3-yl)biphenyl-3-yl]-1,3,5-triazine (abbreviation: TmPPPyTz), 9-(4,6-diphenyl-1,3,5-triazin-2-yl)-9′-phenyl-9H,9′H-3,3′-bicarbazole (abbreviation: CzT), or 2-{3-[3-(dibenzothiophen-4-yl)phenyl]phenyl}-4,6-diphenyl-1,3,5-triazine (abbreviation: mDBtBPTzn); and a heterocyclic compound having a pyridine skeleton such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be given. Among the above-described materials, the heterocyclic compound having a diazine skeleton, the heterocyclic compound having a triazine skeleton, and the heterocyclic compound having a pyridine skeleton have high reliability and are thus preferable. The heterocyclic compound having a diazine (pyrimidine or pyrazine) skeleton and the heterocyclic compound having a triazine skeleton have an excellent electron-transport property and contribute to a decrease in drive voltage.

An n-type compound semiconductor may also be used, and an oxide such as titanium oxide (TiO₂), zinc oxide (ZnO), silicon oxide (SiO₂), tin oxide (SnO₂), tungsten oxide (WO₃), tantalum oxide (Ta₂O₃), barium titanate (BaTiO₃), barium zirconate (BaZrO₃), zirconium oxide (ZrO₂), hafnium oxide (HfO₂), aluminum oxide (Al₂O₃), yttrium oxide (Y₂O₃), or zirconium silicate (ZrSiO₄); a nitride such as silicon nitride (Si₃N₄); cadmium sulfide (CdS); zinc selenide (ZnSe); or zinc sulfide (ZnS) can be used, for example.

A high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), poly[(9,9-dioctylfluorene-2,7-diyl)-co-(2,2′-bipyridine-6,6′-diyl)] (abbreviation: PF-BPy), poly(9,9-dioctylfluorene-2,7-diyl) (abbreviation: F8), or poly[(9,9-dioctylfluorene-2,7-diyl)-alt-(benzo[2,1,3]thiadiazole-4,8-diyl)] (abbreviation: F8BT) can also be used.

Furthermore, a substance having a condensed aromatic hydrocarbon ring such as 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 9-phenyl-3-[4-(10-phenyl-9-anthryl)phenyl]-9H-carbazole (abbreviation:PCzPA), 4-[3-(9,10-diphenyl-2-anthryl)phenyl]dibenzofuran (abbreviation: 2mDBFPPA-II), t-BuDNA, or 9-(2-naphthyl)-10-[4-(1-naphthyl)phenyl]anthracene (abbreviation: BH-1), in particular, a substance having an anthracene skeleton is preferably selected because of having a high electron-transport property and being capable of suppressing diffusion of an alkali metal or an alkaline earth metal. Note that the electron mobility of the first electron-transport material is preferably higher than that of the second electron-transport material.

In addition, the first electron-transport material preferably has a fluorescence quantum yield of 0.5 or more. This is because in the case where holes leak from the light-emitting layer 113 including the metal-halide perovskite material having a high hole-transport property to the first electron-transport layer 114-1 to form an excited state of the first electron-transport material, excitation energy can be transferred to the metal-halide perovskite material by utilizing energy transfer by Förster mechanism, so that emission efficiency of the light-emitting layer 113 can be increased. From this viewpoint, using a substance having an anthracene skeleton with relatively large energy gap and high fluorescence quantum yield as the first electron-transport material is effective.

As the second electron-transport material, a material which facilitates electron injection from the cathode 102 is preferably used. In particular, a substance which facilitates the electron injection by interacting with the alkali metal or the alkaline earth metal provided as the electron-injection buffer layer 115 is preferably used as the second electron-transport material because electron injection to the layer 103 containing a light-emitting substance becomes easier.

As the second electron-transport material, a substance having a six-membered heteroaromatic ring including nitrogen such as bathocuproine (abbreviation: BCP), 2,9-bis(naphthalen-2-yl)-4,7-diphenyl-1,10-phenanthroline (abbreviation: NBPhen), 4,4′-di(1,10-phenanthrolin-2-yl)biphenyl (abbreviation: Phen2BP), 2,2′-(3,3′-phenylene)bis(9-phenyl-1,10-phenanthroline) (abbreviation: mPPhen2P), 2,2′-[2,2′-bipyridine-5,6-diylbis(biphenyl-4,4′-diyl)] bisbenzoxazole (abbreviation: BOxP2BPy), 2,2′-[2-(bipyridin-2-yl)pyridine-5,6-diylbis(biphenyl-4,4′-diyl)]bisbenzoxazole (abbreviation: BOxP2PyPm), 1,3,5-tri[3-(3-pyridyl)phenyl]benzene (abbreviation: TmPyPB), 1,3-bis[3,5-di(pyridin-3-yl)phenyl]benzene (abbreviation: BmPyPhB), 3,3′,5,5′-tetra[(m-pyridyl)-phen-3-yl]biphenyl (abbreviation: BP4mPy), 2-(naphthalen-2-yl)-4,7-diphenyl-1,10-phenanthro line (abbreviation: HNBPhen), 3,3′,5,5′-tetra[(m-pyridyl)-phen-3-yl]biphenyl, 2,9-diphenyl-1,10-phenanthroline (abbreviation: 2,9DPPhen), or 3,4,7,8-tetramethyl-1,10-phenanthroline (abbreviation: TMePhen) is preferable. In particular, a substance having a 2,2′-bipyridine skeleton facilitates electron injection from the cathode, and a phenanthroline derivative is particularly preferable because of its high electron-transport property.

As the electron-injection buffer layer 115, an alkali metal, an alkaline earth metal, or a compound thereof such as lithium fluoride (LiF), cesium fluoride (CsF), or calcium fluoride (CaF₂) is preferably used. Alternatively, a layer that contains a substance having an electron-transport property and an alkali metal, an alkaline earth metal, a compound thereof, or an electride may be used. Examples of the electride include a substance in which electrons are added at high concentration to a calcium oxide-aluminum oxide.

Although the first electron-transport layer 114-1, the second electron-transport layer 114-2, and the electron-injection buffer layer 115 can be formed by a vacuum evaporation method, they may be formed by another method as well.

The stacked structure and each component of the layer 103 containing a light-emitting substance on the cathode 102 side of the light-emitting layer 113 have been described above. Next, the stacked structure and each component of the layer 103 containing a light-emitting substance on the anode 101 side of the light-emitting layer 113 will be described.

For the light-emitting layer using the metal-halide perovskite material as a light-emitting substance, the hole-injection layer 111 and the hole-transport layer 112 can be formed using materials similar to those used in an OLED element. However, because a film of the metal-halide perovskite material can be formed by a wet process such as spin coating or blade coating, it is preferable to form the hole-injection layer 111 and the hole-transport layer 112 also by a wet process.

In the case where the hole-transport layer 112 is formed by a wet process, it can be formed using a high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacryla mide] (abbreviation: PTPDMA), or poly[N,N-bis(4-butylphenyl)-N,N-bis(phenyl)benzidine] (abbreviation: Poly-TPD).

In the case where the hole-injection layer 111 is formed by a wet process, it can be formed using a conductive high-molecular compound to which an acid is added, such as a poly(ethylenedioxythiophene)/poly(styrenesulfonic acid) aqueous solution (PEDOT/PSS), a polyaniline/camphor sulfonic acid aqueous solution (PANI/CSA), PTPDES, Et-PTPDEK, PPBA, or polyaniline/poly(styrenesulfonic acid) (PANI/PSS), for example.

A method other than a wet process may be used to form the hole-transport layer 112 and the hole-injection layer 111.

In this case, the hole-injection layer 111 is formed using a first substance having a relatively high acceptor property. Preferably, the hole-injection layer 111 is formed using a composite material in which the first substance having an acceptor property and a second substance having a hole-transport property are mixed. As the first substance, a substance having an acceptor property with respect to the second substance is used. The first substance draws electrons from the second substance, so that electrons are generated in the first substance. In the second substance from which electrons are drawn, holes are generated. By an electric field, the drawn electrons flow to the anode 101 and the generated holes are injected to the light-emitting layer 113 through the hole-transport layer 112.

The first substance is preferably a transition metal oxide, an oxide of a metal belonging to any of Groups 4 to 8 in the periodic table, an organic compound having an electron-withdrawing group (a halogen group or a cyano group), or the like.

As the transition metal oxide or the oxide of a metal belonging to any of Groups 4 to 8 in the periodic table, a vanadium oxide, a niobium oxide, a tantalum oxide, a chromium oxide, a molybdenum oxide, a tungsten oxide, a manganese oxide, a rhenium oxide, a titanium oxide, a ruthenium oxide, a zirconium oxide, a hafnium oxide, or a silver oxide is preferable because of its high electron acceptor property. A molybdenum oxide is particularly preferable because of its high stability in the air, low hygroscopicity, and high handiness.

Examples of the organic compound having an electron-withdrawing group (a halogen group or a cyano group) include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), and 1,3,4,5,7,8-hexafluorotetracyano-naphthoquinodimethane (abbreviation: F6-TCNNQ). A compound in which electron-withdrawing groups are bonded to a condensed aromatic ring having a plurality of hetero atoms, like HAT-CN, is particularly preferable because it is thermally stable.

The second substance is a substance having a hole-transport property, and has a hole mobility greater than or equal to 10⁻⁶ cm²/Vs. Examples of the material of the second substance include aromatic amines such as N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B); carbazole derivatives such as 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene; and aromatic hydrocarbons such as 2-tert-butyl-9,10-di(2-naphthyflanthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyflanthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, pentacene, coronene, rubrene, perylene, and 2,5,8,11-tetra(tert-butyl)perylene. The aromatic hydrocarbon may have a vinyl skeleton. As the aromatic hydrocarbon having a vinyl group, the following are given for example: 4,4′-bis(2,2-diphenylvinyl)biphenyl (abbreviation: DPVBi); 9,10-bis[4-(2,2-diphenylvinyl)phenyl]anthracene (abbreviation: DPVPA); and the like. Furthermore, a compound having an aromatic amine skeleton such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(Spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yephenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); or a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used. Among the above-described materials, a compound having an aromatic amine skeleton and a compound having a carbazole skeleton are preferable because these compounds are highly reliable and have high hole-transport properties to contribute to a reduction in drive voltage.

The hole-transport layer 112 can be formed using any of the above-described materials for the second substance.

The anode 101 is preferably formed using, for example, any of metals, alloys, and electrically conductive compounds with a high work function (specifically, a work function of 4.0 eV or more) and mixtures thereof. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by application of a sol-gel method or the like. In an example of the formation method, indium oxide-zinc oxide is deposited by a sputtering method using a target obtained by adding zinc oxide to indium oxide at greater than or equal to 1 wt % and less than or equal to 20 wt %. Furthermore, indium oxide containing tungsten oxide and zinc oxide (IWZO) can be deposited by a sputtering method using a target in which tungsten oxide and zinc oxide are added to indium oxide at greater than or equal to 0.5 wt % and less than or equal to 5 wt % and greater than or equal to 0.1 wt % and less than or equal to 1 wt %, respectively. Other examples include gold (Au), platinum (Pt), nickel (Ni), tungsten (W), chromium (Cr), molybdenum (Mo), iron (Fe), cobalt (Co), copper (Cu), palladium (Pd), aluminum (Al), and nitrides of metal materials (e.g., titanium nitride). Graphene can also be used. In the case where the hole-injection layer 111 includes a composite material including the first substance and the second substance, an electrode material other than the above can be selected regardless of the work function.

Examples of a substance contained in the cathode 102 include an element belonging to Group 1 or 2 in the periodic table such as an alkali metal (e.g., lithium (Li) or cesium (Cs)), magnesium (Mg), calcium (Ca), or strontium (Sr) or an alloy containing the element (MgAg or AlLi); a rare earth metal such as europium (Eu) or ytterbium (Yb) or an alloy containing the metal; ITO; indium oxide-tin oxide containing silicon or silicon oxide; indium oxide-zinc oxide; and indium oxide containing tungsten oxide and zinc oxide (IWZO). Any of a variety of conductive materials such as aluminum (Al), silver (Ag), indium tin oxide (ITO), and indium oxide-tin oxide containing silicon or silicon oxide can be used for the cathode 102. A dry method such as a vacuum evaporation method or a sputtering method, an ink-jet method, a spin coating method, or the like can be used for depositing these conductive materials. Alternatively, a wet method using a sol-gel method, or a wet method using a paste of a metal material can be used.

Instead of the electron-injection buffer layer 115, a charge-generation layer 116 may be provided (FIG. 1B). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the above-described materials that can be used for the hole-injection layer 111, in particular, the composite material. The p-type layer 117 may be formed by stacking a film containing the above-described acceptor material as a material included in the composite material and a film containing the above-described hole-transport material. When a potential is applied to the p-type layer 117, electrons are injected into the second electron-transport layer 114-2 and holes are injected into the cathode 102; thus, the light-emitting element operates.

Note that the charge-generation layer 116 preferably includes either an electron-relay layer 118 or an electron-injection buffer layer 119 or both in addition to the p-type layer 117.

The electron-relay layer 118 contains at least the substance having an electron-transport property and has a function of preventing an interaction between the electron-injection buffer layer 119 and the p-type layer 117 and smoothly transferring electrons. The LUMO level of the substance with an electron-transport property contained in the electron-relay layer 118 is preferably between the LUMO level of an acceptor substance in the p-type layer 117 and the LUMO level of a substance contained in a layer of the second electron-transport layer 114-2 in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

A substance having a high electron-injection property can be used for the electron-injection buffer layer 119. For example, an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)) can be used.

In the case where the electron-injection buffer layer 119 contains the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound of the above metal (e.g., an alkali metal compound (including an oxide such as lithium oxide, a halide, and a carbonate such as lithium carbonate or cesium carbonate), an alkaline earth metal compound (including an oxide, a halide, and a carbonate), and a rare earth metal compound (including an oxide, a halide, and a carbonate)). Note that as the substance having an electron-transport property, a material similar to the above-described materials used for the first electron-transport layer 114-1 or the second electron-transport layer 114-2 can be used.

Further, any of a variety of methods can be used for forming the layer 103 containing a light-emitting substance, regardless of whether it is a dry process or a wet process. For example, a vacuum evaporation method or a wet process (e.g., a spin coating method, a casting method, a die coating method, a blade coating method, a roll coating method, an ink-jet method, a printing method (e.g., a gravure printing method, an offset printing method, or a screen printing method), a spray coating method, a curtain coating method, or a Langmuir-Blodgett method) can be used.

Different methods may be used to form the electrodes or the layers described above.

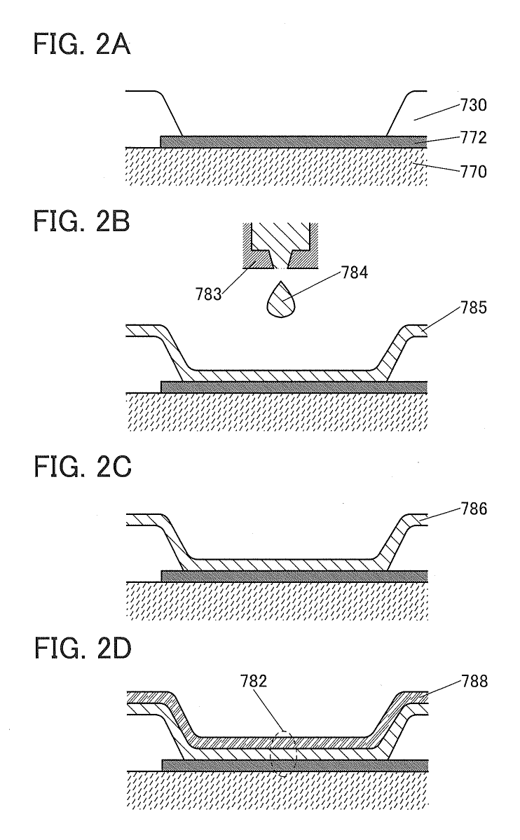

Here, a method for forming a layer 786 containing a light-emitting substance by a droplet discharge method is described with reference to FIGS. 2A to 2D. FIGS. 2A to 2D are cross-sectional views illustrating the method for forming the layer 786 containing a light-emitting substance.

First, a conductive film 772 is formed over a planarization insulating film 770, and an insulating film 730 is formed to cover part of the conductive film 772 (see FIG. 2A).

Then, a droplet 784 is discharged to an exposed portion of the conductive film 772, which is an opening of the insulating film 730, from a droplet discharge apparatus 783, so that a layer 785 containing a composition is formed. The droplet 784 is a composition containing a solvent and is attached to the conductive film 772 (see FIG. 2B).

Note that the step of discharging the droplet 784 may be performed under reduced pressure.

Next, the solvent is removed from the layer 785 containing a composition, and the resulting layer is solidified to form the layer 786 containing a light-emitting substance (see FIG. 2C).

The solvent may be removed by drying or heating.

Next, a conductive film 788 is formed over the layer 786 containing a light-emitting substance; thus, a light-emitting element 782 is completed (see FIG. 2D).

When the layer 786 containing a light-emitting substance is formed by a droplet discharge method as described above, the composition can be selectively discharged; accordingly, waste of material can be reduced. Furthermore, a lithography process or the like for shaping is not needed, and thus, the process can be simplified and cost reduction can be achieved.

The droplet discharge method described above is a general term for a means including a nozzle equipped with a composition discharge opening or a means to discharge droplets such as a head having one or a plurality of nozzles.

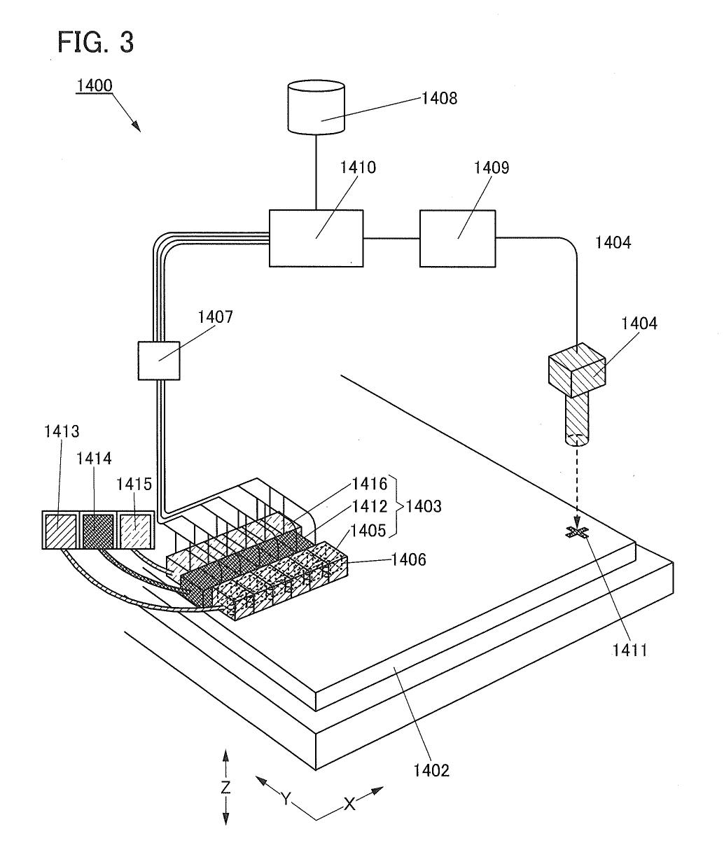

Next, a droplet discharge apparatus used for the droplet discharge method is described with reference to FIG. 3. FIG. 3 is a conceptual diagram illustrating a droplet discharge apparatus 1400.

The droplet discharge apparatus 1400 includes a droplet discharge means 1403. In addition, the droplet discharge means 1403 is equipped with a head 1405, a head 1412, and a head 1416.

The heads 1405 and 1412 are connected to a control means 1407, and this control means 1407 is controlled by a computer 1410; thus, a preprogrammed pattern can be drawn.

The drawing may be conducted at a timing, for example, based on a marker 1411 formed over a substrate 1402. Alternatively, the reference point may be determined on the basis of an outer edge of the substrate 1402. Here, the marker 1411 is detected by an imaging means 1404 and converted into a digital signal by an image processing means 1409. Then, the digital signal is recognized by the computer 1410, and then, a control signal is generated and transmitted to the control means 1407.

An image sensor or the like using a charge coupled device (CCD) or a complementary metal-oxide-semiconductor (CMOS) can be used as the imaging means 1404. Note that information about a pattern to be formed over the substrate 1402 is stored in a storage medium 1408, and a control signal is transmitted to the control means 1407 based on the information, so that each of the heads 1405, 1412, and 1416 of the droplet discharge means 1403 can be individually controlled. A material to be discharged is supplied to the heads 1405, 1412, and 1416 from material supply sources 1413, 1414, and 1415, respectively, through pipes.

Inside each of the heads 1405, 1412, and 1416, a space as indicated by a dotted line 1406 to be filled with a liquid material and a nozzle which is a discharge outlet are provided. Although it is not shown, an inside structure of the head 1412 is similar to that of the head 1405. When the nozzle sizes of the heads 1405 and 1412 are different from each other, different materials with different widths can be discharged simultaneously. Each head can discharge and draw a plurality of light-emitting materials. In the case of drawing over a large area, the same material can be simultaneously discharged to be drawn from a plurality of nozzles in order to improve throughput. When a large substrate is used, the heads 1405, 1412, and 1416 can freely scan the substrate in the directions indicated by arrows X, Y, and Z in FIG. 3, and a region in which a pattern is drawn can be freely set. Thus, a plurality of the same patterns can be drawn over one substrate.

A step of discharging the composition may be performed under reduced pressure. Also, a substrate may be heated when the composition is discharged. After discharging the composition, either drying or baking or both of them is performed. Both the drying and baking are heat treatments but different in purpose, temperature, and time period. The steps of drying and baking are performed under normal pressure or under reduced pressure by laser irradiation, rapid thermal annealing, heating using a heating furnace, or the like. Note that the timing of the heat treatment and the number of times of the heat treatment are not particularly limited. The temperature for performing each of the steps of drying and baking in a favorable manner depends on the materials of the substrate and the properties of the composition.

In the above-described manner, the layer 786 containing a light-emitting substance can be formed with the droplet discharge apparatus.

In the case where the layer 786 containing a light-emitting substance is formed with the droplet discharge apparatus, the layer 786 containing a light-emitting substance can be formed by a wet process using a composition in which a variety of organic materials or a metal-halide perovskite material are dissolved in a solvent. In that case, the following various organic solvents can be used to form a coating composition: benzene, toluene, xylene, mesitylene, tetrahydrofuran, dioxane, ethanol, methanol, n-propanol, isopropanol, n-butanol, t-butanol, acetonitrile, dimethylsulfoxide, dimethylformamide, chloroform, methylene chloride, carbon tetrachloride, ethyl acetate, hexane, cyclohexane, and the like. In particular, less polar benzene derivatives such as benzene, toluene, xylene, and mesitylene are preferable because a solution with a suitable concentration can be obtained and the material contained in ink can be prevented from deteriorating due to oxidation or the like. Furthermore, to achieve a uniform film or a film with a uniform thickness, a solvent with a boiling point of 100° C. or higher is preferably used, and further preferably, toluene, xylene, or mesitylene is used.

Note that the above-described structure can be combined as appropriate with any of the structures in this embodiment and the other embodiment.

Because of including two electron-transport layers, a light-emitting element of one embodiment of the present invention in which the metal-halide perovskite material having the above-described structure is used as a light-emitting material can improve carrier balance. Consequently, the light-emitting element can exhibit favorable light emission efficiency. Furthermore, the electron-transport layer is formed using the material which suppresses diffusion of an alkali metal or an alkaline earth metal, so that diffusion of an alkali metal or an alkaline earth metal, which adversely affects light emission of the light-emitting material, can be suppressed. Accordingly, high emission efficiency can be achieved. A light-emitting element having such a structure can efficiently produce light emission from quantum dots of the metal-halide perovskite material due to band-to-band transition, showing a significantly high external quantum efficiency exceeding 5% of the theoretical limit of an OLED that uses a fluorescent substance.

Next, an embodiment of a light-emitting element with a structure in which a plurality of light-emitting units are stacked (this type of light-emitting element is also referred to as a stacked light-emitting element) is described with reference to FIG. 1C. This light-emitting element includes a plurality of light-emitting units between an anode and a cathode. One light-emitting unit has the same structure as the layer 103 containing a light-emitting substance illustrated in FIG. 1A. In other words, the light-emitting element illustrated in FIG. 1A or 1B includes a single light-emitting unit, and the light-emitting element illustrated in FIG. 1C includes a plurality of light-emitting units.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the anode 101 and the cathode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when a voltage is applied between the first electrode 501 and the second electrode 502. That is, in FIG. 1C, the charge-generation layer 513 injects electrons into the first light-emitting unit 511 and holes into the second light-emitting unit 512 when a voltage is applied so that the potential of the first electrode becomes higher than the potential of the second electrode.

The charge-generation layer 513 preferably has a structure similar to the structure of the charge-generation layer 116 described with reference to FIG. 1B. The composite material of an organic compound and a metal oxide has a high carrier-injection property and a high carrier-transport property; thus, low-voltage driving and low-current driving can be achieved. Note that when a surface of a light-emitting unit on the anode side is in contact with the charge-generation layer 513, the charge-generation layer 513 can also serve as a hole-injection layer of the light-emitting unit; thus, a hole-injection layer is not necessarily formed in the light-emitting unit.

In the case where the electron-injection buffer layer 119 is provided in the charge-generation layer 513, the electron-injection buffer layer serves as the electron-injection buffer layer in the light-emitting unit on the anode side and the light-emitting unit does not necessarily further need an electron-injection layer.

The light-emitting element including two light-emitting units is described with reference to FIG. 1C; however, the present invention can be similarly applied to a light-emitting element in which three or more light-emitting units are stacked. With a plurality of light-emitting units partitioned by the charge-generation layer 513 between a pair of electrodes as in the light-emitting element according to this embodiment, it is possible to provide an element which can emit light with high luminance with the current density kept low and has a long lifetime. Moreover, a light-emitting device with low power consumption, which can be driven at a low voltage, can be achieved.

When light-emitting units have different emission colors, light emission of desired color can be obtained as a whole light-emitting element.

### Embodiment 2

In this embodiment, a light-emitting device including a light-emitting element described in Embodiment 1 will be described.

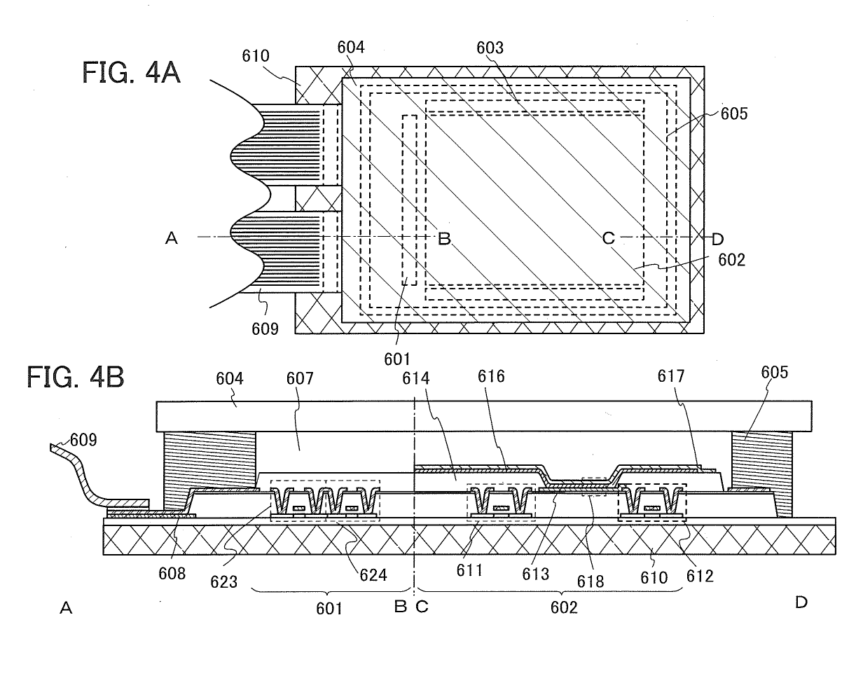

A light-emitting device of one embodiment of the present invention will be described with reference to FIGS. 4A and 4B. Note that FIG. 4A is a top view of the light-emitting device and FIG. 4B is a cross-sectional view taken along the lines A-B and C-D in FIG. 4A. The light-emitting device includes a driver circuit portion (source line driver circuit) 601, a pixel portion 602, and a driver circuit portion (gate line driver circuit) 603 which are illustrated with dotted lines. Furthermore, reference numeral 604 denotes a sealing substrate and reference numeral 605 denotes a sealant. A portion surrounded by the sealant 605 is a space 607.

Note that a lead wiring 608 is a wiring for transmitting signals to be input to the source line driver circuit 601 and the gate line driver circuit 603 and for receiving a video signal, a clock signal, a start signal, a reset signal, and the like from an FPC (flexible printed circuit) 609 functioning as an external input terminal. Although only the FPC is illustrated here, a printed wiring board (PWB) may be attached to the FPC. The light-emitting device in this specification includes, in its category, not only the light-emitting device itself but also the light-emitting device provided with the FPC or the PWB.

Next, a cross-sectional structure is described with reference to FIG. 4B. The driver circuit portion and the pixel portion are formed over an element substrate 610. Here, the source line driver circuit 601, which is the driver circuit portion, and one pixel of the pixel portion 602 are illustrated.

In the source line driver circuit 601, a CMOS circuit is formed in which an n-channel FET 623 and a p-channel FET 624 are combined. The driver circuit may be formed using various circuits such as a CMOS circuit, a PMOS circuit, or an NMOS circuit. Although a driver-integrated type where the driver circuit is formed over the substrate is described in this embodiment, a driver circuit is not necessarily formed over a substrate; a driver circuit may be formed outside a substrate.

The pixel portion 602 includes a plurality of pixels including a switching FET 611, a current controlling FET 612, and a first electrode 613 electrically connected to a drain of the current controlling FET 612. One embodiment of the present invention is not limited to this structure. The pixel portion may include three or more FETs and a capacitor in combination.

The kind and crystallinity of a semiconductor used for the FETs is not particularly limited; an amorphous semiconductor or a crystalline semiconductor may be used. Examples of the semiconductor used for the FETs include Group 13 semiconductor, Group 14 semiconductor, compound semiconductor, oxide semiconductor, and organic semiconductor materials. Oxide semiconductors are particularly preferable. Examples of the oxide semiconductor include an In—Ga oxide and an In-M-Zn oxide (M is Al, Ga, Y, Zr, La, Ce, or Nd). Note that an oxide semiconductor material that has an energy gap of 2 eV or more, preferably 2.5 eV or more, further preferably 3 eV or more is preferably used, in which case the off-state current of the transistors can be reduced.

Note that an insulator 614 is formed so as to cover an end portion of the first electrode 613. The insulator 614 can be formed using a positive photosensitive acrylic resin film here.

In order to improve the coverage, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). Moreover, either a negative photosensitive resin or a positive photosensitive resin can be used as the insulator 614.

An EL layer 616 and a second electrode 617 are formed over the first electrode 613. The first electrode 613, the EL layer 616, and the second electrode 617 correspond, respectively, to the anode 101, the layer 103 containing a light-emitting substance, and the cathode 102 in FIG. 1A or 1B.

The EL layer 616 preferably contains an organometallic complex. The organometallic complex is preferably used as an emission center substance in the light-emitting layer.

The sealing substrate 604 is attached using the sealant 605 to the element substrate 610; thus, a light-emitting element 618 is provided in the space 607 surrounded by the element substrate 610, the sealing substrate 604, and the sealant 605. The space 607 is filled with filler, and may be filled with an inert gas (e.g., nitrogen or argon), the sealant 605, or the like. It is preferable that the sealing substrate be provided with a recessed portion and a drying agent be provided in the recessed portion, in which case deterioration due to influence of moisture can be suppressed.

An epoxy-based resin or glass frit is preferably used for the sealant 605. A material used for them is desirably a material which does not transmit moisture or oxygen as much as possible. As the element substrate 610 and the sealing substrate 604, for example, a glass substrate, a quartz substrate, or a plastic substrate formed of fiber reinforced plastic (FRP), polyvinyl fluoride (PVF), polyester, or acrylic can be used.

Note that in this specification and the like, a transistor or a light-emitting element can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of the flexible substrate, the attachment film, the base material film, or the like are as follows: plastic typified by polyethylene terephthalate (PET), polyethylene naphthalate (PEN), and polyether sulfone (PES). Another example is a synthetic resin such as acrylic. Alternatively, polytetrafluoroethylene (PTFE), polypropylene, polyester, polyvinyl fluoride, polyvinyl chloride, or the like can be used. Alternatively, polyamide, polyimide, aramid, epoxy, an inorganic film formed by evaporation, paper, or the like can be used. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Alternatively, a flexible substrate may be used as the substrate, and the transistor or the light-emitting element may be provided directly over the flexible substrate. Still alternatively, a separation layer may be provided between a substrate and the transistor or between the substrate and the light-emitting element. The separation layer can be used when part or the whole of a semiconductor device formed over the separation layer is separated from the substrate and transferred onto another substrate. In such a case, the transistor can be transferred to a substrate having low heat resistance or a flexible substrate as well. For the above separation layer, a stack including inorganic films, which are a tungsten film and a silicon oxide film, or an organic resin film of polyimide or the like formed over a substrate can be used, for example.

In other words, a transistor or a light-emitting element may be formed using one substrate, and then transferred to another substrate. Examples of the substrate to which the transistor or the light-emitting element is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a transistor with excellent properties or a transistor with low power consumption can be formed, a device with high durability and high heat resistance can be provided, or a reduction in weight or thickness can be achieved.

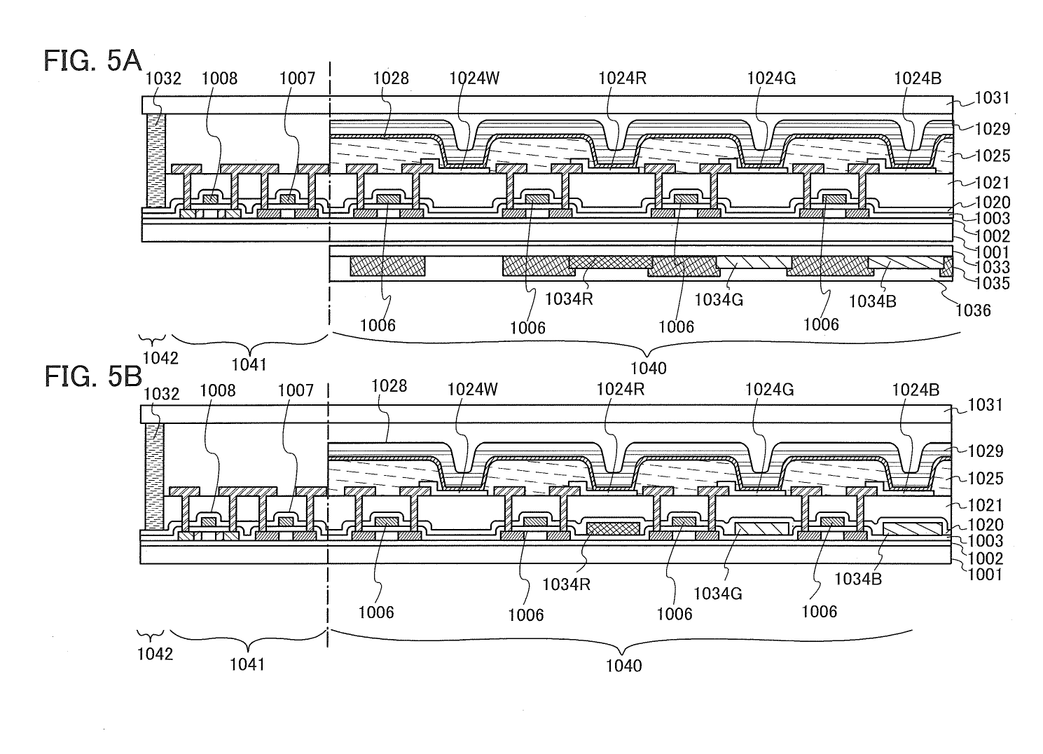

FIGS. 5A and 5B each illustrate an example of a light-emitting device in which full color display is achieved by combining a light-emitting element that exhibits white light emission with coloring layers (color filters) and the like. In FIG. 5A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting elements, a partition 1025, an EL layer 1028, a cathode 1029 of the light-emitting elements, a sealing substrate 1031, a sealant 1032, and the like are illustrated.

In FIG. 5A, coloring layers (a red coloring layer 1034R, a green coloring layer 1034G, and a blue coloring layer 1034B) are provided on a transparent base material 1033. A black layer (a black matrix) 1035 may be additionally provided. The transparent base material 1033 provided with the coloring layers and the black layer is positioned and fixed to the substrate 1001. Note that the coloring layers and the black layer are covered with an overcoat layer. In FIG. 5A, light emitted from some of the light-emitting layers does not pass through the coloring layers, while light emitted from the others of the light-emitting layers passes through the coloring layers. Since light which does not pass through the coloring layers is white and light which passes through any one of the coloring layers is red, blue, or green, an image can be displayed using pixels of the four colors.

FIG. 5B illustrates an example in which the coloring layers (the red coloring layer 1034R, the green coloring layer 1034G, and the blue coloring layer 1034B) are formed between the gate insulating film 1003 and the first interlayer insulating film 1020. As in this structure, the coloring layers may be provided between the substrate 1001 and the sealing substrate 1031.

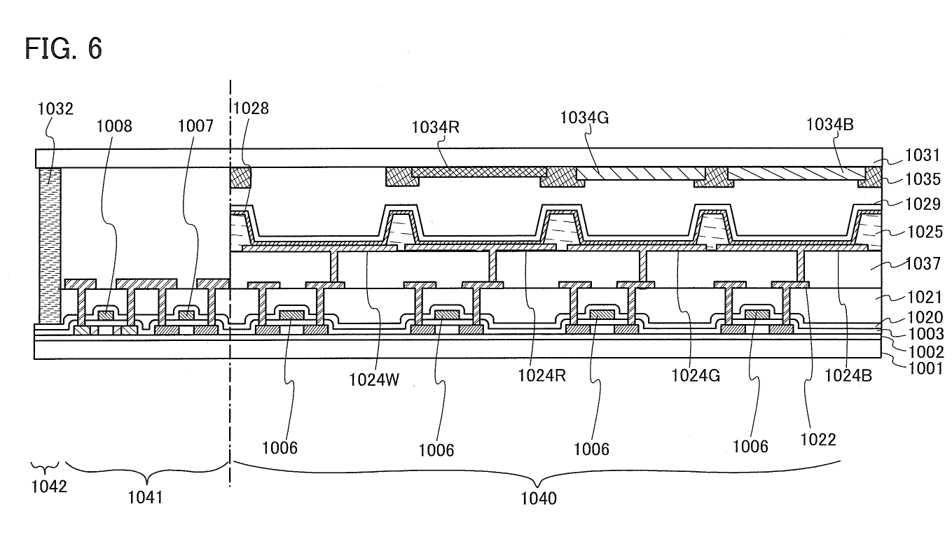

The above-described light-emitting device has a structure in which light is extracted from the substrate 1001 side where the FETs are formed (a bottom emission structure), but may have a structure in which light is extracted from the sealing substrate 1031 side (a top emission structure). FIG. 6 is a cross-sectional view of a light-emitting device having a top emission structure. In that case, a substrate which does not transmit light can be used as the substrate 1001. The process up to the step of forming of a connection electrode which connects the FET and the anode of the light-emitting element is performed in a manner similar to that of the light-emitting device having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, or can be formed using any other various materials.

The first electrodes 1024W, 1024R, 1024G, and 1024B of the light-emitting elements each function as an anode here, but may function as a cathode. Furthermore, in the case of the light-emitting device having a top emission structure as illustrated in FIG. 6, the first electrodes are preferably reflective electrodes. The EL layer 1028 is formed to have a structure similar to the structure of the layer 103 containing a light-emitting substance in FIG. 1A or 1B, with which white light emission can be obtained.

In the case of a top emission structure as illustrated in FIG. 6, sealing can be performed with the sealing substrate 1031 on which the coloring layers (the red coloring layer 1034R, the green coloring layer 1034G, and the blue coloring layer 1034B) are provided. The sealing substrate 1031 may be provided with the black layer (the black matrix) 1035 which is positioned between pixels. The coloring layers (the red coloring layer 1034R, the green coloring layer 1034G, and the blue coloring layer 1034B) and the black layer may be covered with the overcoat layer. Note that a light-transmitting substrate is used as the sealing substrate 1031.

Although an example in which full color display is performed using four colors of red, green, blue, and white is shown here, there is no particular limitation and full color display using three colors of red, green, and blue or four colors of red, green, blue, and yellow may be performed.

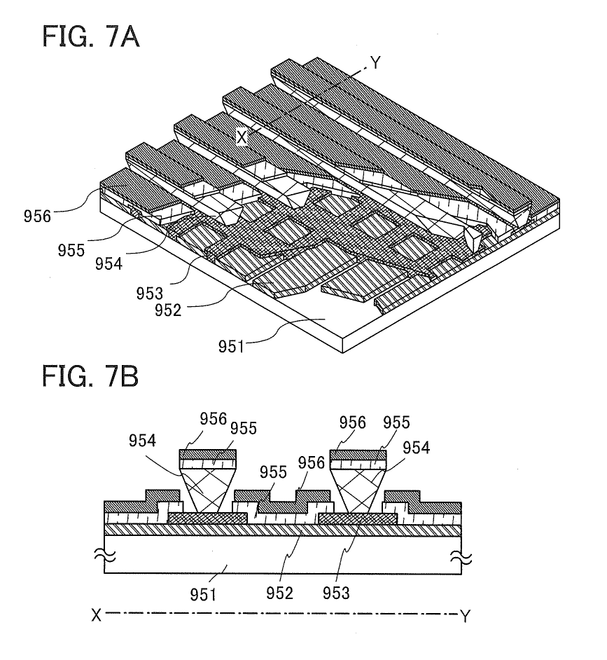

FIGS. 7A and 7B illustrate a passive matrix light-emitting device of one embodiment of the present invention. FIG. 7A is a perspective view of a light-emitting device, and FIG. 7B is a cross-sectional view taken along the line X-Y of FIG. 7A. In FIGS. 7A and 7B, an EL layer 955 is provided between an electrode 952 and an electrode 956 over a substrate 951. An end portion of the electrode 952 is covered with an insulating layer 953. A partition layer 954 is provided over the insulating layer 953. Sidewalls of the partition layer 954 are aslope such that the distance between the sidewalls is gradually narrowed toward the surface of the substrate. That is, a cross section in a short side direction of the partition layer 954 is a trapezoidal shape, and a lower side (the side facing the same direction as the plane direction of the insulating layer 953 and touching the insulating layer 953) is shorter than an upper side (the side facing the same direction as the plane direction of the insulating layer 953, and not touching the insulating layer 953). By providing the partition layer 954 in this manner, defects of the light-emitting element due to static charge and the like can be prevented.

Since many minute light-emitting elements arranged in a matrix can be controlled with the FETs formed in the pixel portion, the above-described light-emitting device can be suitably used as a display device for displaying images.

### <<Lighting Device>>

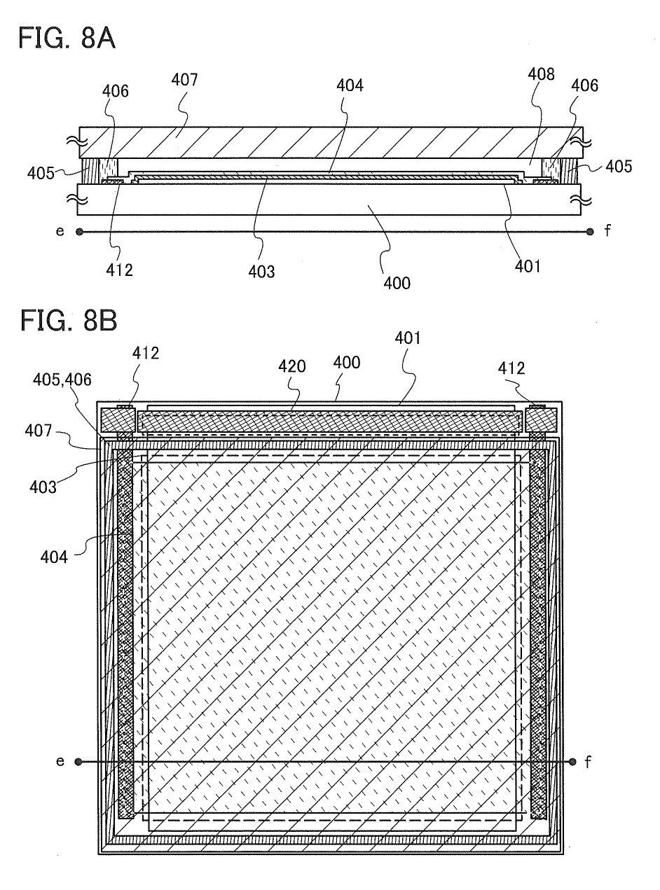

A lighting device of one embodiment of the present invention is described with reference to FIGS. 8A and 8B. FIG. 8B is a top view of the lighting device, and FIG. 8A is a cross-sectional view taken along the line e-f in FIG. 8B.

In the lighting device, a first electrode 401 is formed over a substrate 400 which is a support and has a light-transmitting property. The first electrode 401 corresponds to the anode 101 in FIGS. 1A and 1B. When light is extracted through the first electrode 401 side, the first electrode 401 is formed using a material having a light-transmitting property.

A pad 412 for applying voltage to a second electrode 404 is provided over the substrate 400.

An EL layer 403 is formed over the first electrode 401. The EL layer 403 corresponds to, for example, the layer 103 containing a light-emitting substance in FIGS. 1A and 1B. For these structures, the corresponding description can be referred to.

The second electrode 404 is formed to cover the EL layer 403. The second electrode 404 corresponds to the cathode 102 in FIG. 1A. The second electrode 404 contains a material having high reflectivity when light is extracted through the first electrode 401 side. The second electrode 404 is connected to the pad 412, whereby voltage is applied thereto.

A light-emitting element is formed with the first electrode 401, the EL layer 403, and the second electrode 404. The light-emitting element is fixed to a sealing substrate 407 with sealants 405 and 406 and sealing is performed, whereby the lighting device is completed. It is possible to use only either the sealant 405 or the sealant 406. In addition, the inner sealant 406 (not shown in FIG. 8B) can be mixed with a desiccant that enables moisture to be adsorbed, which results in improved reliability.

When part of the pad 412 and part of the first electrode 401 are extended to the outside of the sealants 405 and 406, the extended parts can function as external input terminals. An IC chip 420 mounted with a converter or the like may be provided over the external input terminals.

### <<Display Device>>

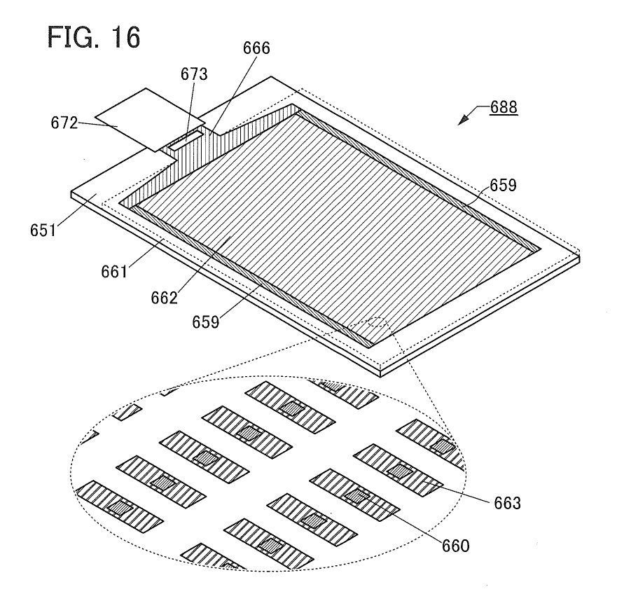

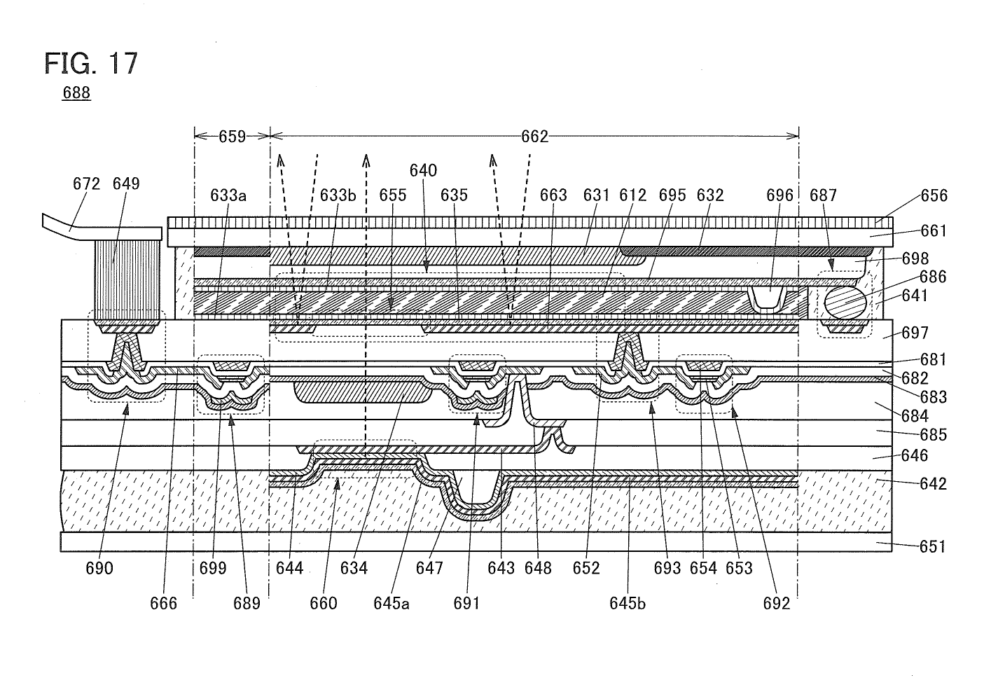

An example of a display panel that can be used for a display portion or the like in a display device including the semiconductor device of one embodiment of the present invention will be described below with reference to FIG. 16 and FIG. 17. The display panel exemplified below includes both a reflective liquid crystal element and a light-emitting element and can display an image in both the transmissive mode and the reflective mode.

FIG. 16 is a schematic perspective view illustrating a display panel 688 of one embodiment of the present invention. In the display panel 688, a substrate 651 and a substrate 661 are attached to each other. In FIG. 16, the substrate 661 is denoted by a dashed line.

The display panel 688 includes a display portion 662, a circuit 659, a wiring 666, and the like. The substrate 651 is provided with the circuit 659, the wiring 666, a conductive film 663 which serves as a pixel electrode, and the like. In the example of FIG. 16, an IC 673 and an FPC 672 are mounted on the substrate 651. Thus, the structure illustrated in FIG. 16 can be referred to as a display module including the display panel 688, the FPC 672, and the IC 673.

As the circuit 659, for example, a circuit functioning as a scan line driver circuit can be used.

The wiring 666 has a function of supplying a signal or electric power to the display portion or the circuit 659. The signal or electric power is input to the wiring 666 from the outside through the FPC 672 or from the IC 673.

FIG. 16 shows an example in which the IC 673 is provided on the substrate 651 by a chip on glass (COG) method or the like. As the IC 673, an IC functioning as a scan line driver circuit, a signal line driver circuit, or the like can be used. Note that it is possible that the IC 673 is not provided when, for example, the display panel 688 includes circuits serving as a scan line driver circuit and a signal line driver circuit and when the circuits serving as a scan line driver circuit and a signal line driver circuit are provided outside and a signal for driving the display panel 688 is input through the FPC 672. Alternatively, the IC 673 may be mounted on the FPC 672 by a chip on film (COF) method or the like.

FIG. 16 also shows an enlarged view of part of the display portion 662. The conductive films 663 included in a plurality of display elements are arranged in a matrix in the display portion 662. The conductive film 663 has a function of reflecting visible light and serves as a reflective electrode of a liquid crystal element 640 described later.

As illustrated in FIG. 16, the conductive film 663 has an opening. A light-emitting element 660 is positioned closer to the substrate 651 than the conductive film 663 is. Light is emitted from the light-emitting element 660 to the substrate 661 side through the opening in the conductive film 663. When the light-emitting element of one embodiment of the present invention is used as the light-emitting element 660, a display panel including a light-emitting element with high emission efficiency can be provided. Furthermore, when the light-emitting element of one embodiment of the present invention is used as the light-emitting element 660, a display panel including a light-emitting element with high color purity can be provided.

### <Cross-Sectional Structure Example>

FIG. 17 shows an example of cross sections of part of a region including the FPC 672, part of a region including the circuit 659, and part of a region including the display portion 662 of the display panel illustrated in FIG. 16.

The display panel includes an insulating film 697 between the substrates 651 and 661. The display panel also includes the light-emitting element 660, a transistor 689, a transistor 691, a transistor 692, a coloring layer 634, and the like between the substrate 651 and the insulating film 697. Furthermore, the display panel includes the liquid crystal element 640, a coloring layer 631, and the like between the insulating film 697 and the substrate 661. The substrate 661 and the insulating film 697 are bonded with an adhesive layer 641. The substrate 651 and the insulating film 697 are bonded with an adhesive layer 642.

The transistor 692 is electrically connected to the liquid crystal element 640 and the transistor 691 is electrically connected to the light-emitting element 660. Since the transistors 691 and 692 are formed on a surface of the insulating film 697 that is on the substrate 651 side, the transistors 691 and 692 can be formed through the same process.

The substrate 661 is provided with the coloring layer 631, a light-blocking film 632, an insulating film 698, a conductive film 695 serving as a common electrode of the liquid crystal element 640, an alignment film 633b, an insulating film 696, and the like. The insulating film 696 serves as a spacer for holding a cell gap of the liquid crystal element 640.

Insulating layers such as an insulating film 681, an insulating film 682, an insulating film 683, an insulating film 684, and an insulating film 685 are provided on the substrate 651 side of the insulating film 697. Part of the insulating film 681 functions as a gate insulating layer of each transistor. The insulating films 682, 683, and 684 are provided to cover each transistor. The insulating film 685 is provided to cover the insulating film 684. The insulating films 684 and 685 each function as a planarization layer. Note that here, the three insulating layers, the insulating films 682, 683, and 684, are provided to cover the transistors and the like; however, one embodiment of the present invention is not limited to this example, and four or more insulating layers, a single insulating layer, or two insulating layers may be provided. The insulating film 684 functioning as a planarization layer is not necessarily provided.

The transistors 689, 691, and 692 each include a conductive film 654 part of which functions as a gate, a conductive film 652 part of which functions as a source or a drain, and a semiconductor film 653. Here, a plurality of layers obtained by processing the same conductive film are shown with the same hatching pattern.

The liquid crystal element 640 is a reflective liquid crystal element. The liquid crystal element 640 has a stacked structure of a conductive film 635, a liquid crystal layer 694, and the conductive film 695. In addition, the conductive film 663 which reflects visible light is provided in contact with the surface of the conductive film 635 that faces the substrate 651. The conductive film 663 includes an opening 655. The conductive films 635 and 695 contain a material that transmits visible light. In addition, an alignment film 633a is provided between the liquid crystal layer 694 and the conductive film 635 and the alignment film 633b is provided between the liquid crystal layer 694 and the conductive film 695. A polarizing plate 656 is provided on an outer surface of the substrate 661.

In the liquid crystal element 640, the conductive film 663 has a function of reflecting visible light and the conductive film 695 has a function of transmitting visible light. Light entering from the substrate 661 side is polarized by the polarizing plate 656, passes through the conductive film 695 and the liquid crystal layer 694, and is reflected by the conductive film 663. Then, the light passes through the liquid crystal layer 694 and the conductive film 695 again and reaches the polarizing plate 656. In this case, the alignment of the liquid crystal is controlled with a voltage that is applied between the conductive film 663 and the conductive film 695, and thus optical modulation of light can be controlled. That is, the intensity of light emitted through the polarizing plate 656 can be controlled. Light excluding light in a particular wavelength region is absorbed by the coloring layer 631, and thus, red light is emitted, for example.

The light-emitting element 660 is a bottom-emission light-emitting element. The light-emitting element 660 has a structure in which a conductive film 643, an EL layer 644, and a conductive film 645b are stacked in this order from the insulating film 697 side. In addition, a conductive film 645a is provided to cover the conductive film 645b. The conductive film 645b contains a material reflecting visible light, and the conductive films 643 and 645a contain a material transmitting visible light. Light is emitted from the light-emitting element 660 to the substrate 661 side through the coloring layer 634, the insulating film 697, the opening 655, the conductive film 695, and the like.

Here, as illustrated in FIG. 17, the conductive film 635 transmitting visible light is preferably provided for the opening 655. Accordingly, the liquid crystal layer 694 is aligned in a region overlapping with the opening 655 as well as in the other regions, so that undesired light leakage due to an alignment defect of the liquid crystal in the boundary portion of these regions can be prevented.

As the polarizing plate 656 provided on an outer surface of the substrate 661, a linear polarizing plate or a circularly polarizing plate can be used. An example of the circularly polarizing plate is a stack including a linear polarizing plate and a quarter-wave retardation plate. Such a structure can reduce reflection of external light. The cell gap, alignment, drive voltage, and the like of the liquid crystal element used as the liquid crystal element 640 are controlled depending on the kind of the polarizing plate so that a desirable contrast can be obtained.

In addition, an insulating film 647 is provided on the insulating film 646 covering an end portion of the conductive film 643. The insulating film 647 has a function of a spacer for preventing the insulating film 697 and the substrate 651 from getting closer than necessary. In the case where the EL layer 644 or the conductive film 645a is formed using a blocking mask (metal mask), the insulating film 647 may have a function of a spacer for preventing the blocking mask from being in contact with a surface on which the EL layer 644 or the conductive film 645a is formed. Note that the insulating film 647 is not necessarily provided.

One of a source and a drain of the transistor 691 is electrically connected to the conductive film 643 of the light-emitting element 660 through a conductive film 648.

One of a source and a drain of the transistor 692 is electrically connected to the conductive film 663 through a connection portion 693. The conductive films 663 and 635 are in contact with and electrically connected to each other. Here, in the connection portion 693, the conductive layers provided on both surfaces of the insulating film 697 are connected to each other through an opening in the insulating film 697.

A connection portion 690 is provided in a region of the substrate 651 that does not overlap the substrate 661. The connection portion 690 is electrically connected to the FPC 672 through a connection layer 649. The connection portion 690 has a structure similar to that of the connection portion 693. On the top surface of the connection portion 690, a conductive layer obtained by processing the same conductive film as the conductive film 635 is exposed. Thus, the connection portion 690 and the FPC 672 can be electrically connected to each other through the connection layer 649.

A connection portion 687 is provided in part of a region where the adhesive layer 641 is provided. In the connection portion 687, the conductive layer obtained by processing the same conductive film as the conductive film 635 is electrically connected to part of the conductive film 695 with a connector 686. Accordingly, a signal or a potential input from the FPC 672 connected to the substrate 651 side can be supplied to the conductive film 695 formed on the substrate 661 side through the connection portion 687.

As the connector 686, a conductive particle can be used, for example. As the conductive particle, a particle of an organic resin, silica, or the like coated with a metal material can be used. It is preferable to use nickel or gold as the metal material because contact resistance can be reduced. It is also preferable to use a particle coated with layers of two or more kinds of metal materials, such as a particle coated with nickel and further with gold. As the connector 686, a material capable of elastic deformation or plastic deformation is preferably used. As illustrated in FIG. 17, the connector 686 which is the conductive particle has a shape that is vertically crushed in some cases. With the crushed shape, the contact area between the connector 686 and a conductive layer electrically connected to the connector 686 can be increased, thereby reducing contact resistance and suppressing the generation of problems such as disconnection.

The connector 686 is preferably provided so as to be covered with the adhesive layer 641. For example, the connector 686 is dispersed in the adhesive layer 641 before curing of the adhesive layer 641.

FIG. 17 illustrates an example of the circuit 659 in which the transistor 689 is provided.

In FIG. 17, as a structure example of the transistors 689 and 691, the semiconductor film 653 where a channel is formed is provided between two gates. One gate is formed using the conductive film 654 and the other gate is formed using a conductive film 699 overlapping with the semiconductor film 653 with the insulating film 682 provided therebetween. Such a structure enables the control of threshold voltages of a transistor. In that case, the two gates may be connected to each other and supplied with the same signal to operate the transistor. Such a transistor can have higher field-effect mobility and thus have higher on-state current than other transistors. Consequently, a circuit capable of high-speed operation can be obtained. Furthermore, the area occupied by a circuit portion can be reduced. The use of the transistor having a high on-state current can reduce signal delay in wirings and can reduce display unevenness even in a display panel that has an increased number of wirings with an increase in size or resolution.

Note that the transistor included in the circuit 659 and the transistor included in the display portion 662 may have the same structure. A plurality of transistors included in the circuit 659 may have the same structure or different structures. A plurality of transistors included in the display portion 662 may have the same structure or different structures.

A material through which impurities such as water and hydrogen do not easily diffuse is preferably used for at least one of the insulating films 682 and 683 which cover the transistors. That is, the insulating film 682 or the insulating film 683 can function as a barrier film. Such a structure can effectively suppress the diffusion of the impurities into the transistors from the outside, and a highly reliable display panel can be provided.

The insulating film 698 is provided on the substrate 661 side to cover the coloring layer 631 and the light-blocking film 632. The insulating film 698 may have a function of a planarization layer. The insulating film 698 enables the conductive film 695 to have an almost flat surface, resulting in a uniform alignment state of the liquid crystal layer 694.

An example of the method for manufacturing the display panel 688 is described. For example, the conductive film 635, the conductive film 663, and the insulating film 697 are formed in order over a support substrate provided with a separation layer, and the transistor 691, the transistor 692, the light-emitting element 660, and the like are formed. Then, the substrate 651 and the support substrate are bonded with the adhesive layer 642. After that, separation is performed at the interface between the separation layer and each of the insulating film 697 and the conductive film 635, whereby the support substrate and the separation layer are removed. Separately, the coloring layer 631, the light-blocking film 632, the conductive film 695, and the like are formed over the substrate 661 in advance. Then, the liquid crystal is dropped onto the substrate 651 or 661 and the substrates 651 and 661 are bonded with the adhesive layer 641, whereby the display panel 688 can be manufactured.

A material for the separation layer can be selected such that separation at the interface with the insulating film 697 and the conductive film 635 occurs. In particular, it is preferable that a stack of a layer including a high-melting-point metal material, such as tungsten, and a layer including an oxide of the metal material be used as the separation layer, and a stack of a plurality of layers, such as a silicon nitride layer, a silicon oxynitride layer, and a silicon nitride oxide layer be used as the insulating film 697 over the separation layer. The use of the high-melting-point metal material for the separation layer can increase the formation temperature of a layer formed in a later step, which reduces impurity concentration and enables a highly reliable display panel.

As the conductive film 635, an oxide or a nitride such as a metal oxide, a metal nitride, or an oxide semiconductor with reduced resistance is preferably used. In the case of using an oxide semiconductor, a material in which at least one of the concentrations of hydrogen, boron, phosphorus, nitrogen, and other impurities and the number of oxygen vacancies is made to be higher than those in a semiconductor layer of a transistor is used for the conductive film 635.

The above components will be described below. Note that the description of the structures having functions similar to those described above is omitted.

### [Adhesive Layer]

As the adhesive layer, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. Alternatively, a two-component type resin may be used. Further alternatively, an adhesive sheet or the like may be used.

Furthermore, the resin may include a drying agent. For example, a substance that adsorbs moisture by chemical adsorption, such as an oxide of an alkaline earth metal (e.g., calcium oxide or barium oxide), can be used. Alternatively, a substance that adsorbs moisture by physical adsorption, such as zeolite or silica gel, may be used. The drying agent is preferably included because it can prevent impurities such as moisture from entering the element, thereby improving the reliability of the display panel.

In addition, it is preferable to mix a filler with a high refractive index or light-scattering member into the resin, in which case light extraction efficiency can be enhanced. For example, titanium oxide, barium oxide, zeolite, zirconium, or the like can be used.

### [Connection Layer]

As the connection layer, an anisotropic conductive film (ACF), an anisotropic conductive paste (ACP), or the like can be used.

### [Coloring Layer]

Examples of the material that can be used for the coloring layers include a metal material, a resin material, and a resin material containing a pigment or dye.

### [Light-Blocking Layer]

Examples of the material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked-layer structure of a film containing a material for a coloring layer that transmits light of a certain color and a film containing a material for a coloring layer that transmits light of another color can be employed. The coloring layer and the light-blocking layer are preferably forming using the same material so that the same manufacturing apparatus can be used and the process can be simplified.

The above is the description of the components.

Next, a manufacturing method example of a display panel using a flexible substrate is described.

Here, layers including a display element, a circuit, a wiring, an electrode, optical members such as a coloring layer and a light-blocking layer, an insulating layer, and the like, are collectively referred to as an element layer. The element layer includes, for example, a display element, and may additionally include a wiring electrically connected to the display element or an element such as a transistor used in a pixel or a circuit.

In addition, here, a flexible member that supports the element layer at the time when the display element is completed (the manufacturing process is finished) is referred to as a substrate. For example, a substrate includes an extremely thin film with a thickness greater than or equal to 10 nm and less than or equal to 300 μm.

As a method for forming an element layer over a flexible substrate provided with an insulating surface, typically, the following two methods can be employed. One of them is to form an element layer directly on the substrate. The other method is to form an element layer over a support substrate that is different from the substrate and then to separate the element layer from the support substrate to be transferred to the substrate. Although not described in detail here, in addition to the above two methods, there is a method in which an element layer is formed over a substrate that does not have flexibility and the substrate is thinned by polishing or the like to have flexibility.

In the case where a material of the substrate has resistance to heat applied in the totaling process of the element layer, it is preferable that the element layer be formed directly on the substrate, in which case a manufacturing process can be simplified. At this time, the element layer is preferably formed in a state where the substrate is fixed to the supporting base, in which case transfer thereof in an apparatus and between apparatuses can be easy.

In the case of employing the method in which the element layer is formed over the supporting base and then transferred to the substrate, first, a separation layer and an insulating layer are stacked over the supporting base, and then the element layer is formed over the insulating layer. Next, the element layer is separated from the supporting base and then transferred to the substrate. At this time, a material may be selected so that the separation occurs at an interface between the supporting base and the separation layer, at an interface between the separation layer and the insulating layer, or in the separation layer. In this method, a high heat resistant material is preferably used for the supporting base or the separation layer, in which case the upper limit of the temperature applied when the element layer is formed can be increased, and an element layer including a more highly reliable element can be formed.

For example, it is preferable that a stack of a layer containing a high-melting-point metal material, such as tungsten, and a layer containing an oxide of the metal material be used as the separation layer, and a stack of a plurality of layers, such as a silicon oxide layer, a silicon nitride layer, a silicon oxynitride layer, and a silicon nitride oxide layer be used as the insulating layer over the separation layer.

The element layer and the supporting base can be separated by applying mechanical power, by etching the separation layer, by injecting a liquid into the separation interface, or the like. Alternatively, separation may be performed by heating or cooling two layers of the separation interface by utilizing a difference in thermal expansion coefficient.

The separation layer is not necessarily provided in the case where the separation can be performed at an interface between the supporting base and the insulating layer.

For example, glass and an organic resin such as polyimide can be used as the supporting base and the insulating layer, respectively. In that case, a separation trigger may be formed by, for example, locally heating part of the organic resin with laser light or the like, or by physically cutting part of or making a hole through the organic resin with a sharp tool, and separation may be performed at an interface between the glass and the organic resin. As the above-described organic resin, a photosensitive material is preferably used because an opening or the like can be easily formed. The above-described laser light preferably has a wavelength region, for example, from visible light to ultraviolet light. For example, light having a wavelength greater than or equal to 200 nm and less than or equal to 400 nm, preferably greater than or equal to 250 nm and less than or equal to 350 nm can be used. In particular, an excimer laser having a wavelength of 308 nm is preferably used because the productivity is increased. Alternatively, a solid-state UV laser (also referred to as a semiconductor UV laser), such as a UV laser having a wavelength of 355 nm which is the third harmonic of an Nd:YAG laser, may be used.

Alternatively, a heat generation layer may be provided between the supporting base and the insulating layer formed of an organic resin, and separation may be performed at an interface between the heat generation layer and the insulating layer by heating the heat generation layer. For the heat generation layer, a material that generates heat when current flows therethrough, a material that generates heat when it absorbs light, a material that generates heat when applied with a magnetic field, and other various materials can be used. For example, a material for the heat generation layer can be selected from a semiconductor, a metal, and an insulator.

In the above-described methods, the insulating layer formed of an organic resin can be used as a substrate after the separation.

The above is the description of the manufacturing method of a flexible display panel.

At least part of the above structure can be implemented in appropriate combination with any of the other structures described in this specification.

### <<Electronic Device>>

Examples of an electronic device of one embodiment of the present invention are described. Examples of the electronic device include a television device (also referred to as a television or a television receiver), a monitor of a computer or the like, a digital camera, a digital video camera, a digital photo frame, a mobile phone (also referred to as a mobile telephone or a mobile phone device), a portable game console, a portable information terminal, an audio reproducing device, and a large-sized game machine such as a pachinko machine. Specific examples of these electronic devices are described below.

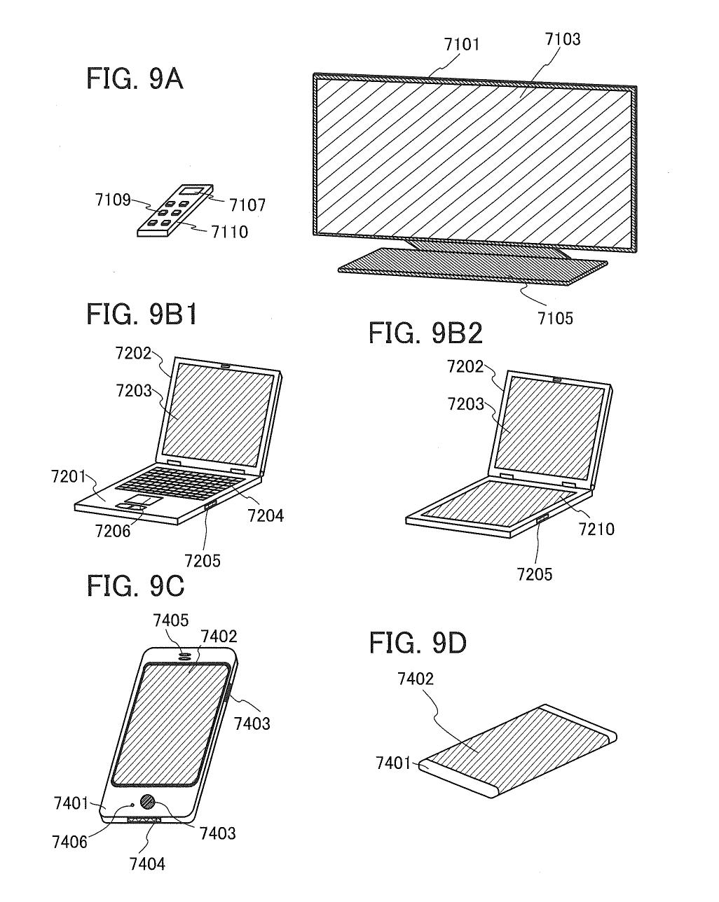

FIG. 9A illustrates an example of a television device. In the television device, a display portion 7103 is incorporated in a housing 7101. In addition, here, the housing 7101 is supported by a stand 7105. Images can be displayed on the display portion 7103, and in the display portion 7103, light-emitting elements are arranged in a matrix.

The television device can be operated with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, and the like. With the use of the receiver, a general television broadcast can be received. Moreover, when the display device is connected to a communication network with or without wires via the modem, one-way (from a sender to a receiver) or two-way (between a sender and a receiver or between receivers) information communication can be performed.

FIG. 9B1 illustrates a computer, which includes a main body 7201, a housing 7202, a display portion 7203, a keyboard 7204, an external connection port 7205, a pointing device 7206, and the like. Note that this computer is manufactured by using light-emitting elements arranged in a matrix in the display portion 7203. The computer illustrated in FIG. 9B1 may have a structure illustrated in FIG. 9B2. The computer illustrated in FIG. 9B2 is provided with a second display portion 7210 instead of the keyboard 7204 and the pointing device 7206. The second display portion 7210 is a touch panel, and input can be performed by operation of display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIGS. 9C and 9D illustrate an example of a portable information terminal. The portable information terminal is provided with a display portion 7402 incorporated in a housing 7401, operation buttons 7403, an external connection port 7404, a speaker 7405, a microphone 7406, and the like. Note that the portable information terminal has the display portion 7402 including light-emitting elements arranged in a matrix.

Information can be input to the portable information terminal illustrated in FIGS. 9C and 9D by touching the display portion 7402 with a finger or the like. In that case, operations such as making a call and creating e-mail can be performed by touching the display portion 7402 with a finger or the like.

There are mainly three screen modes of the display portion 7402. The first mode is a display mode mainly for displaying images. The second mode is an input mode mainly for inputting data such as text. The third mode is a display-and-input mode in which two modes of the display mode and the input mode are combined.

For example, in the case of making a call or creating e-mail, a text input mode mainly for inputting text is selected for the display portion 7402 so that text displayed on a screen can be input. In that case, it is preferable to display a keyboard or number buttons on almost the entire screen of the display portion 7402.

When a detection device including a sensor such as a gyroscope sensor or an acceleration sensor for sensing inclination is provided inside the portable information terminal, screen display of the display portion 7402 can be automatically changed by deter mining the orientation of the portable information terminal (whether the portable information terminal is placed horizontally or vertically).

The screen modes are switched by touching the display portion 7402 or operating the operation buttons 7403 of the housing 7401. Alternatively, the screen modes can be switched depending on kinds of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed within a specified period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken by touch on the display portion 7402 with the palm or the finger, whereby personal authentication can be performed. Furthermore, by providing a backlight or a sensing light source which emits near-infrared light in the display portion, an image of a finger vein, a palm vein, or the like can be taken.

Note that in the above electronic devices, any of the structures described in this specification can be combined as appropriate.

The display portion preferably includes a light-emitting element of one embodiment of the present invention. The light-emitting element can have high emission efficiency. In addition, the light-emitting element can be driven with low drive voltage. Thus, the electronic device including the light-emitting element of one embodiment of the present invention can have low power consumption.

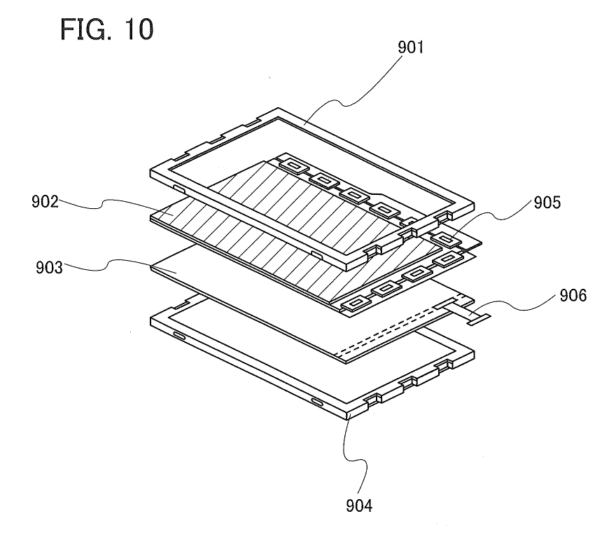

FIG. 10 illustrates an example of a liquid crystal display device including the light-emitting element for a backlight. The liquid crystal display device illustrated in FIG. 10 includes a housing 901, a liquid crystal layer 902, a backlight unit 903, and a housing 904. The liquid crystal layer 902 is connected to a driver IC 905. The light-emitting element is used for the backlight unit 903, to which current is supplied through a terminal 906.

As the light-emitting element, a light-emitting element of one embodiment of the present invention is preferably used. By including the light-emitting element, the backlight of the liquid crystal display device can have low power consumption.

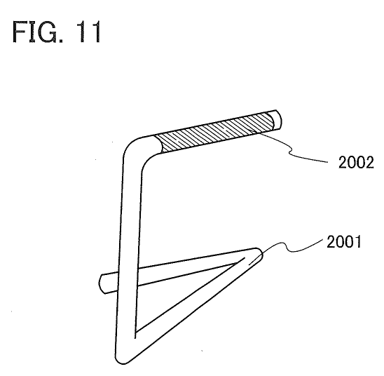

FIG. 11 illustrates an example of a desk lamp of one embodiment of the present invention. The desk lamp illustrated in FIG. 11 includes a housing 2001 and a light source 2002, and a lighting device including a light-emitting element is used as the light source 2002.

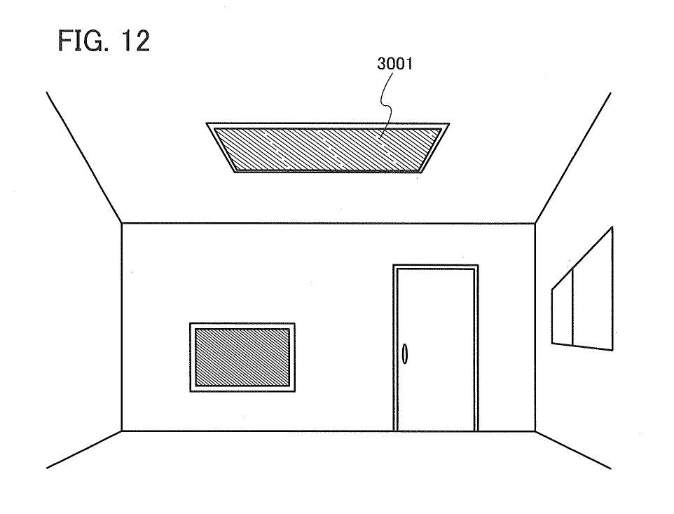

FIG. 12 illustrates an example of an indoor lighting device 3001. The light-emitting element of one embodiment of the present invention is preferably used in the lighting device 3001.

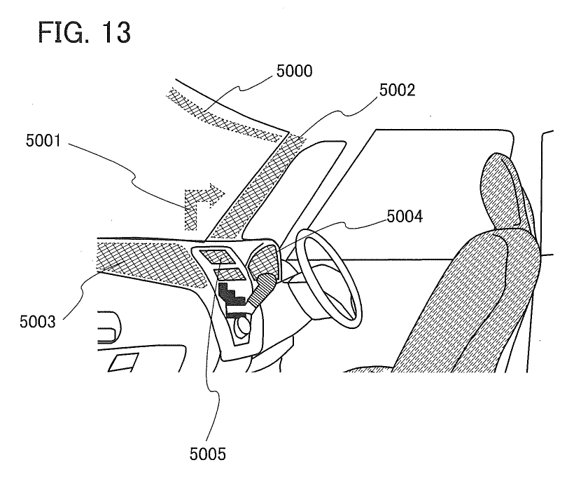

An automobile of one embodiment of the present invention is illustrated in FIG. 13. In the automobile, light-emitting elements are used for a windshield and a dashboard. Display regions 5000 to 5005 are provided by using the light-emitting elements. Display regions 5000 to 5005 are preferably formed by using the light-emitting elements of one embodiment of the present invention. This suppresses power consumption of the display regions 5000 to 5005, showing suitability for use in an automobile.

The display regions 5000 and 5001 are display devices which are provided in the automobile windshield and which include the light-emitting elements. When a first electrode and a second electrode are formed of electrodes having light-transmitting properties in these light-emitting elements, what is called a see-through display device, through which the opposite side can be seen, can be obtained. Such see-through display devices can be provided even in the windshield of the automobile, without hindering the vision. Note that in the case where a transistor for driving the light-emitting element is provided, a transistor having a light-transmitting property, such as an organic transistor using an organic semiconductor material or a transistor using an oxide semiconductor, is preferably used.

The display region 5002 is a display device which is provided in a pillar portion and which includes the light-emitting element. The display region 5002 can compensate for the view hindered by the pillar portion by showing an image taken by an imaging unit provided in the car body. Similarly, the display region 5003 provided in the dashboard can compensate for the view hindered by the car body by showing an image taken by an imaging unit provided in the outside of the car body, which leads to elimination of blind areas and enhancement of safety. Showing an image so as to compensate for the area which a driver cannot see makes it possible for the driver to confirm safety easily and comfortably.

The display region 5004 and the display region 5005 can provide a variety of kinds of information such as navigation information, a speedometer, a tachometer, a mileage, a fuel meter, a gearshift indicator, and air-condition setting. The content or layout of the display can be changed freely by a user as appropriate. Note that such information can also be shown by the display regions 5000 to 5003. The display regions 5000 to 5005 can also be used as lighting devices.

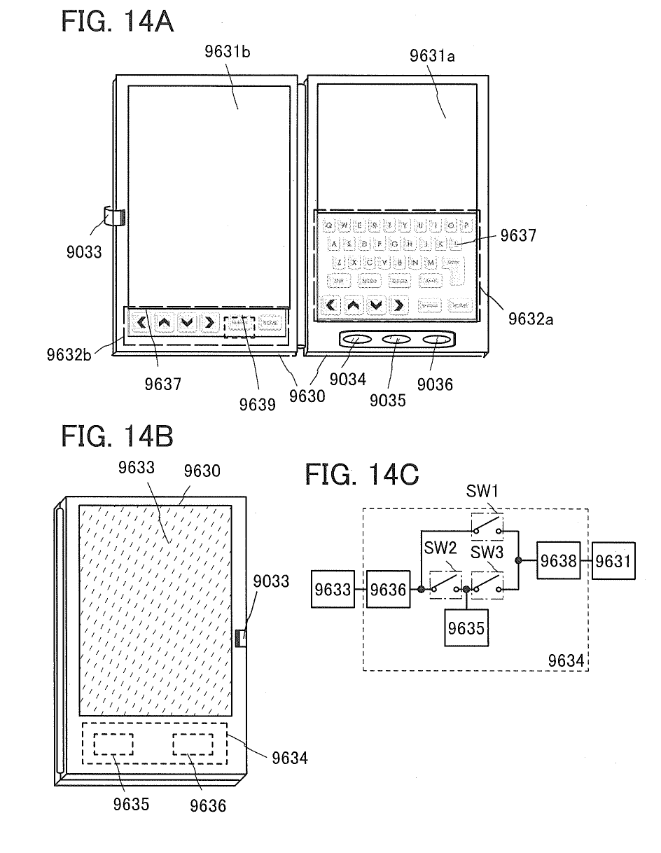

FIGS. 14A and 14B illustrate an example of a foldable tablet terminal. In FIG. 14A, the tablet terminal is opened, and includes a housing 9630, a display portion 9631a, a display portion 9631b, a switch 9034 for switching display modes, a power switch 9035, a switch 9036 for switching to power-saving mode, and a fastener 9033. Note that in the tablet terminal, one or both of the display portion 9631a and the display portion 9631b are formed using a light-emitting device which includes the light-emitting element of one embodiment of the present invention.

Part of the display portion 9631a can be a touch panel region 9632a and data can be input when a displayed operation key 9637 is touched. Although a structure in which a half region in the display portion 9631a has only a display function and the other half region has a touch panel function is illustrated as an example, the structure of the display portion 9631a is not limited thereto. The whole region in the display portion 9631a may have a touch panel function. For example, the display portion 9631a can display keyboard buttons in the whole region to be a touch panel, and the display portion 9631b can be used as a display screen.

Like the display portion 9631a, part of the display portion 9631b can be a touch panel region 9632b. When a switching button 9639 for showing/hiding a keyboard on the touch panel is touched with a finger, a stylus, or the like, the keyboard can be displayed on the display portion 9631b.

Touch input can be performed in the touch panel region 9632a and the touch panel region 9632b at the same time.

The switch 9034 for switching display modes can switch the display between portrait mode, landscape mode, and the like, and between monochrome display and color display, for example. The switch 9036 for switching to power-saving mode can control display luminance to be optimal in accordance with the amount of external light in use of the tablet terminal which is sensed by an optical sensor incorporated in the tablet terminal. Another sensing device including a sensor for sensing inclination, such as a gyroscope sensor or an acceleration sensor, may be incorporated in the tablet terminal, in addition to the optical sensor.

Note that FIG. 14A illustrates an example in which the display portion 9631a and the display portion 9631b have the same display area; however, without limitation thereon, one of the display portions may be different from the other display portion in size and display quality. For example, one display panel may be capable of higher-definition display than the other display panel.

FIG. 14B illustrates the tablet terminal which is folded. The tablet terminal in this embodiment includes the housing 9630, a solar cell 9633, a charge and discharge control circuit 9634, a battery 9635, and a DCDC converter 9636. Note that in FIG. 14B, an example in which the charge and discharge control circuit 9634 includes the battery 9635 and the DCDC converter 9636 is illustrated.

Since the tablet terminal can be folded, the housing 9630 can be closed when the tablet terminal is not used. As a result, the display portion 9631a and the display portion 9631b can be protected; thus, a tablet terminal which has excellent durability and excellent reliability in terms of long-term use can be provided.

In addition, the tablet terminal illustrated in FIGS. 14A and 14B can have a function of displaying a variety of kinds of data (e.g., a still image, a moving image, and a text image), a function of displaying a calendar, a date, the time, or the like on the display portion, a touch-input function of operating or editing the data displayed on the display portion by touch input, a function of controlling processing by a variety of kinds of software (programs), and the like.

The solar cell 9633 provided on a surface of the tablet terminal can supply power to the touch panel, the display portion, a video signal processing portion, or the like. Note that the solar cell 9633 is preferably provided on one or two surfaces of the housing 9630, in which case the battery 9635 can be charged efficiently.

The structure and the operation of the charge and discharge control circuit 9634 illustrated in FIG. 14B are described with reference to a block diagram in FIG. 14C. FIG. 14C illustrates the solar cell 9633, the battery 9635, the DCDC converter 9636, a converter 9638, switches SW1 to SW3, and the display portion 9631. The battery 9635, the DCDC converter 9636, the converter 9638, and the switches SW1 to SW3 correspond to the charge and discharge control circuit 9634 illustrated in FIG. 14B.

First, an example of the operation in the case where power is generated by the solar cell 9633 using external light is described. The voltage of power generated by the solar cell is raised or lowered by the DCDC converter 9636 so that the power has a voltage for charging the battery 9635. Then, when power charged by the solar cell 9633 is used for the operation of the display portion 9631, the switch SW1 is turned on and the voltage of the power is raised or lowered by the converter 9638 so as to be voltage needed for the display portion 9631. In addition, when display on the display portion 9631 is not performed, the switch SW1 is turned off and the switch SW2 is turned on so that charge of the battery 9635 may be performed.

Although the solar cell 9633 is described as an example of a power generation means, the power generation means is not particularly limited, and the battery 9635 may be charged by another power generation means such as a piezoelectric element or a thermoelectric conversion element (Peltier element). The battery 9635 may be charged by a non-contact power transmission module capable of performing charging by transmitting and receiving power wirelessly (without contact), or any of the other charge means used in combination, and the power generation means is not necessarily provided.

One embodiment of the present invention is not limited to the tablet terminal having the shape illustrated in FIGS. 14A to 14C as long as the display portion 9631 is included.

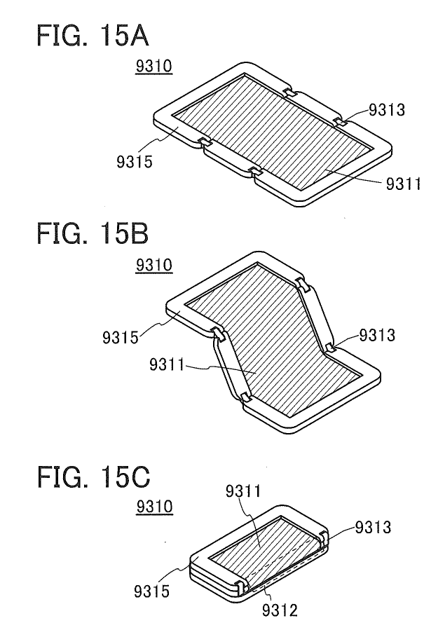

FIGS. 15A to 15C illustrate a foldable portable information terminal 9310. FIG. 15A illustrates the portable information terminal 9310 which is opened. FIG. 15B illustrates the portable information terminal 9310 which is being opened or being folded. FIG. 15C illustrates the portable information terminal 9310 which is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By bending the display panel 9311 at a connection portion between two housings 9315 with the use of the hinges 9313, the portable information terminal 9310 can be reversibly changed in shape from an opened state to a folded state. A light-emitting device of one embodiment of the present invention can be used for the display panel 9311. A display region 9312 in the display panel 9311 is a display region that is positioned at a side surface of the portable information terminal 9310 that is folded. On the display region 9312, information icons, file shortcuts of frequently used applications or programs, and the like can be displayed, and confirmation of information and start of application can be smoothly performed.

### Example 1

In this example, fabrication methods and characteristics of light-emitting elements of one embodiment of the present invention and a comparative light-emitting element will be described in detail.

### (Fabrication Method of Light-Emitting Element 1)

First, a film of indium tin oxide including silicon oxide (ITSO) was formed over a glass substrate by a sputtering method, so that the anode 101 was formed. The film thickness was 70 nm and the electrode area was 2 mm×2 mm.

Next, pretreatment for forming the light-emitting element over the substrate was performed, in which a surface of the substrate was washed with water and baked at 200° C. for 1 hour, and then UV ozone treatment was performed for 370 seconds.

Then, the substrate was fixed to a substrate holder of a spin coater so that a surface on the anode 101 side faced upward, and an aqueous solution of poly(3,4-ethylenedioxythiophene)/poly(styrenesulfonic acid) (PEDOT/PSS) purchased from H.C. Starck (Product No. CREVIOS P VP AI 4083) was applied onto the anode 101. Then, rotation was performed at 4000 rpm for 60 seconds. This substrate was vacuum baked in a chamber at a pressure of 1 Pa to 10 Pa at 130° C. for 15 minutes and then cooled down for approximately 30 minutes; thus, the hole-injection layer 111 was formed.

Next, the substrate over which the hole-injection layer 111 was formed was introduced into a glove box containing a nitrogen atmosphere. An o-dichlorobenzene solution containing 10 mg/mL of poly[N,N′-bis(4-butylphenyl)-N,N-bis(phenyl)benzidine] (abbreviation: Poly-TPD) purchased from Luminescence Technology Corp. (Product No. LT-N149) was applied onto the hole-injection layer 111. Then, rotation was performed at 4000 rpm for 60 seconds. This substrate was vacuum baked in a chamber at a pressure of 1 Pa to 10 Pa at 130° C. for 15 minutes and then cooled down for approximately 30 minutes; thus, the hole-transport layer 112 was formed.

Next, a toluene solution containing 10 mg/mL of quantum dots of the metal-halide perovskite material purchased from PlasmaChem (Product No. PL-QD-PSK-515, Lot No. AA150715d) was applied onto the hole-transport layer 112. Then, rotation was performed at 500 rpm for 60 seconds. This substrate was vacuum baked in a chamber at a pressure of 1 Pa to 10 Pa at 80° C. for 30 minutes and then cooled down for approximately 30 minutes; thus, the light-emitting layer 113 was formed.

Next, the substrate provided with the light-emitting layer 113 was introduced into a vacuum evaporation device the inside of which was reduced in pressure to approximately 10⁻⁴ Pa and fixed to a substrate holder so that a surface on the light-emitting layer 113 side faced downward. Then, 2,2′,2″-(1,3,5-benzenetriyl)tris(1-phenyl-1H-benzimidazole) (abbreviation: TPBI) was deposited on the light-emitting layer 113 by an evaporation method using resistive heating to a thickness of 25 nm; thus, the electron-transport layer 114 was formed.

After that, as the electron-injection buffer layer 115, lithium fluoride (LiF) was deposited on the electron-transport layer 114 by evaporation to a thickness of 1 nm.

Then, as the cathode 102, aluminum (Al) was deposited on the electron-injection buffer layer 115 to a thickness of 200 nm.

Next, in a glove box containing a nitrogen atmosphere, Light-emitting Element 1 was sealed by fixing a counter glass substrate for sealing to a glass substrate on which the organic material was deposited with a sealant for an organic EL device. Specifically, a drying agent was attached, the sealant was applied to the counter glass substrate so as to surround the organic material, and the counter glass substrate and the substrate over which the organic material were formed were bonded to each other. Then, irradiation with ultraviolet light having a wavelength of 365 urn at 6 J/cm² and heat treatment at 80° C. for one hour were performed. Through the above-described process, Light-emitting Element 1 was obtained.

### (Fabrication Method of Light-Emitting Element 2)

Light-emitting Element 2 was formed in the same way as Light-emitting Element 1 except that the electron-transport layer 114 was formed of two layers of not only TPBI but also 2,9-bis(naphthalen-2-yl)-4,7-diphenyl-1,10-phenanthroline (abbreviation: NBPhen). After the TPBI layer was formed in a manner similar to that of Light-emitting Element 1, the NBPhen layer was formed by evaporation to a thickness of 15 nm.

### (Fabrication Method of Light-Emitting Element 3)

Light-emitting Element 3 was formed in the same way as Light-emitting Element 2 except that 7-[4-(10-phenyl-9-anthryl)phenyl]-7H-dibenzo[c,g]carbazole (abbreviation: cgDBCzPA) was used instead of TPBI in the electron-transport layer 114.

Light-emitting Elements 1 to 3 were each sealed using a glass substrate in a glove box containing a nitrogen atmosphere so as not to be exposed to the air (specifically, a sealant was applied to surround the element and UV treatment and heat treatment at 80° C. for 1 hour were performed at the time of sealing). Then, the initial characteristics of Light-emitting Elements 1 to 3 were measured. The measurement was carried out at room temperature (under an atmosphere maintained at 25° C.).

The element structures of Light-emitting Elements 1 to 3 are shown in the table below.

TABLE 1

| | | | | Electron-transport layer | | |
|---|---|---|---|---|---|---|
| | | | | 1st electron- | 2nd electron- | |
| | Hole- | Hole- | Light- | transport | transport | Electron- |
| | injection | transport | emitting | layer | layer | injection |
| | layer | layer | layer | 25 nm | 15 nm | layer |
| Light-emitting | PEDOT/PSS | Poly-TPD | Per-QD | TPBI | — | 1 nm |
| Element 1 | | | | | | |
| Light-emitting | | | | | NBPhen | LiF |
| Element 2 | | | | | | |
| Light-emitting | | | | cgDBCzPA | | |
| Element 3 | | | | | | |

### <Characteristics of Light-Emitting Elements>

Next, characteristics of Light-emitting Elements 1 to 3 fabricated in the above-described manner were measured. Luminances and CIE chromaticities were measured with a luminance colorimeter (BM-5AS manufactured by Topcon Technohouse Corporation), and electroluminescence spectra were measured with a multi-channel spectrometer (PMA-11 manufactured by Hamamatsu Photonics K.K.).

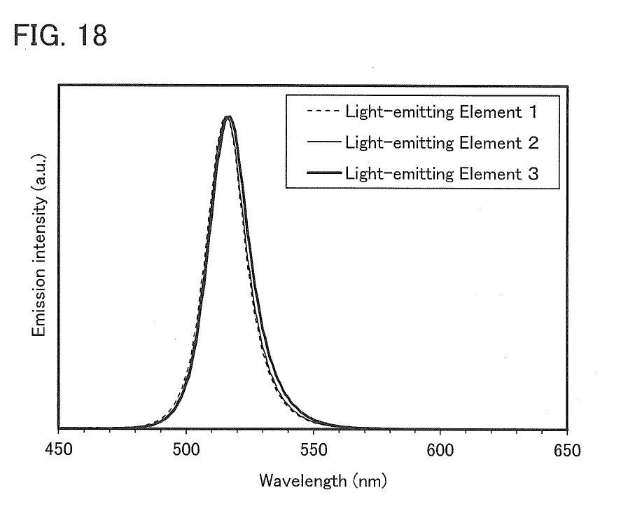

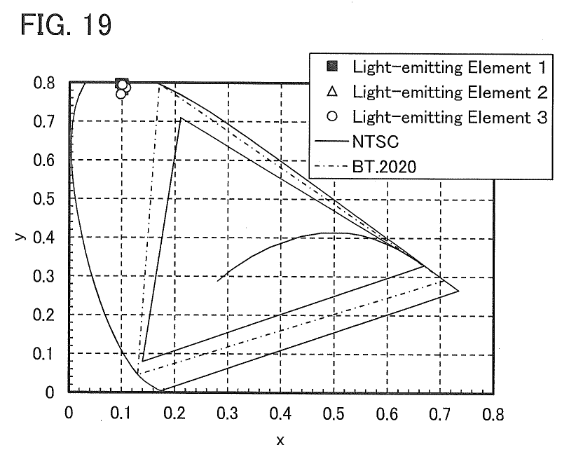

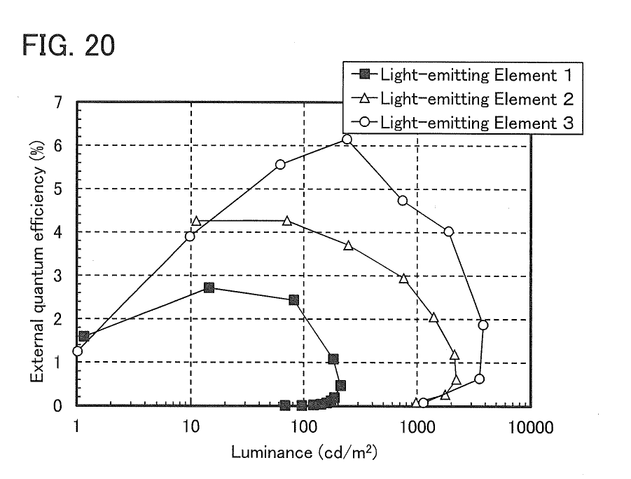

FIG. 18, FIG. 19, and FIG. 20 show emission spectra, CIE chromaticity coordinates, and external quantum efficiency-luminance characteristics, respectively, of Light-emitting Elements 1 to 3.

FIG. 18 and FIG. 19 indicate that Light-emitting Elements 1 to 3 each exhibited green light emission with extremely narrow half widths and high color purities. The chromaticities sufficiently cover the NTSC standard and the BT.2020 standard.

According to FIG. 20, Light-emitting Elements 2 and 3 of one embodiment of the present invention have extremely favorable characteristics, i.e., external quantum efficiencies of more than 4%. In particular, Light-emitting Element 3 has an external quantum efficiency of 6.2%. This is probably because two electron-transport layers are included in Light-emitting Elements 2 and 3, which are the light-emitting elements of the present invention, and the second electron-transport layer positioned on the electron-injection layer side facilitates electron injection to the layer containing the light-emitting substance. NBPhen used as the second electron-transport layer interacts with lithium of LiF that is the electron-injection layer; accordingly, easier electron injection to the organic layer is possible.

Furthermore, because the metal-halide perovskite material has a favorable hole-transport property, a light-emitting element using the metal-halide perovskite material as a light-emitting substance might hold excessive holes. However, because the first electron-transport layer of Light-emitting Element 3 has a favorable electron-transport property, a good carrier balance can be achieved in the light-emitting layer, leading to an improvement in emission efficiency.

Moreover, Light-emitting Element 3 uses cgDBCzPA, which is an anthracene derivative, as the first electron-transport layer. The anthracene derivative has a high electron-transport property and can effectively suppress diffusion of lithium, which influences light emission of the metal-halide perovskite material. Using such an anthracene derivative as the first electron-transport layer enabled Light-emitting Element 3 to have extremely favorable emission efficiency.

In general, in an organic EL element using a fluorescent substance, when the light extraction efficiency is assumed to be 20%, the theoretical limit of the external quantum efficiency is 5% according to the spin selection rule because the exciton generation efficiency in the following theoretical equation is 25% at maximum.

EQE=γ×α×Φ×χ

In the above equation, γ is a carrier balance factor, α is exciton generation efficiency, Φ is emission quantum efficiency, and χ is light extraction efficiency.

The PL quantum yield of quantum dots of the metal-halide perovskite material used this time is 56%. When the carrier balance factory γ is assumed to be 100% and the light extraction efficiency χ is assumed to be 20% in Light-emitting Element 3 exhibiting an external quantum efficiency of 6.2%, the exciton generation efficiency α is 55% by calculation, which exceeds the limit in fluorescence under the spin selection rule. This high exciton generation efficiency was effectively obtained because light emission from quantum dots of the metal-halide perovskite material is derived from band-to-band transition and Light-emitting Element 3 includes two electron-transport layers having the structure of one embodiment of the present invention.

This application is based on Japanese Patent Application Serial No. 2016-233190 filed with Japan Patent Office on Nov. 30, 2016 and Japanese Patent Application Serial No. 2017-010585 filed with Japan Patent Office on Jan. 24, 2017, the entire contents of which are hereby incorporated by reference.

What is claimed is:

1. A light-emitting element comprising:
an anode;
a cathode; and
a layer comprising a light-emitting substance between the anode and the cathode,
wherein the layer comprising the light-emitting substance comprises a light-emitting layer, a first electron-transport layer, and a second electron-transport layer,
wherein the light-emitting layer and the first electron-transport layer are in contact with each other,
wherein the first electron-transport layer and the second electron-transport layer are in contact with each other,
wherein the first electron-transport layer and the second electron-transport layer are positioned between the light-emitting layer and the cathode,
wherein the light-emitting layer comprises a metal-halide perovskite material,
wherein the first electron-transport layer comprises a first electron-transport material, and
wherein the second electron-transport layer comprises a second electron-transport material.

2. The light-emitting element according to claim 1, further comprising an electron-injection buffer layer between the second electron-transport layer and the cathode.

3. The light-emitting element according to claim 2, wherein the electron-injection buffer layer comprises an alkali metal or an alkaline earth metal.

4. The light-emitting element according to claim 2, wherein the second electron-transport material interacts with an alkali metal or an alkaline earth metal to form a state which facilitates electron injection from the cathode to the layer comprising the light-emitting substance.

5. The light-emitting element according to claim 1, wherein the second electron-transport material comprises a six-membered heteroaromatic ring including nitrogen.

6. The light-emitting element according to claim 1, wherein the second electron-transport material comprises a 2,2′-bipyridine skeleton.

7. The light-emitting element according to claim 1, wherein the second electron-transport material comprises a phenanthroline derivative.

8. The light-emitting element according to claim 1, wherein the first electron-transport material comprises a condensed aromatic hydrocarbon ring.

9. The light-emitting element according to claim 1, wherein the first electron-transport material comprises an anthracene derivative.

10. The light-emitting element according to claim 1, wherein the metal-halide perovskite material is a particle comprising a longest part being 1 μm or less.

11. The light-emitting element according to claim 1, wherein the metal-halide perovskite material has a layered structure in which a perovskite layer and an organic layer are stacked.

12. A light-emitting element comprising:
an anode;
a cathode; and
a layer comprising a light-emitting substance between the anode and the cathode,
wherein the layer comprising the light-emitting substance comprises a light-emitting layer, a first electron-transport layer, and a second electron-transport layer,
wherein the light-emitting layer and the first electron-transport layer are in contact with each other,
wherein the first electron-transport layer and the second electron-transport layer are in contact with each other,
wherein the first electron-transport layer and the second electron-transport layer are positioned between the light-emitting layer and the cathode,
wherein the light-emitting layer comprises a metal-halide perovskite material represented by General Formula (SA)MX₃, General Formula (LA)₂(SA)ₙ₋₁MₙX₃ₙ₊₁, or General Formula (PA)(SA)ₙ₋₁MₙX₃ₙ₊₁,
wherein the first electron-transport layer comprises a first electron-transport material,
wherein the second electron-transport layer comprises a second electron-transport material,
wherein M represents a divalent metal ion, X represents a halogen ion, and n represents an integer of 1 to 10,
wherein LA is an ammonium ion represented by R¹—NH₃⁺,
wherein R¹ represents any one or more of an alkyl group having 2 to 20 carbon atoms, an aryl group having 6 to 20 carbon atoms, and a heteroaryl group having 4 to 20 carbon atoms,
wherein in the case where R¹ represents two or more of the alkyl group having 2 to 20 carbon atoms, the aryl group having 6 to 20 carbon atoms, and the heteroaryl group having 4 to 20 carbon atoms, a plurality of groups of the same kind or different kinds are used as R¹,
wherein PA represents NH₃⁺—R²—NH₃⁺, NH₃⁺—R³—R⁴—R⁵—NH₃⁺, or a part or whole of a polymer including ammonium cations, and the valence of PA is +2,
wherein R² represents a single bond or an alkylene group having 1 to 12 carbon atoms, R³ and R⁵ independently represent a single bond or an alkylene group having 1 to 12 carbon atoms, and R⁴ represents one or two of a cyclohexylene group and an arylene group having 6 to 14 carbon atoms,
wherein in the case where R⁴ represents two of the cyclohexylene group and the arylene group having 6 to 14 carbon atoms, a plurality of groups of the same kind or different kinds are used as R⁴, and
wherein SA represents a monovalent metal ion or an ammonium ion represented by R⁶—NH₃⁺ in which R⁶ is an alkyl group having 1 to 6 carbon atoms.

13. The light-emitting element according to claim 12,
wherein LA is represented by any of General Formulae (A-1) to (A-11) and General Formulae (B-1) to (B-6) 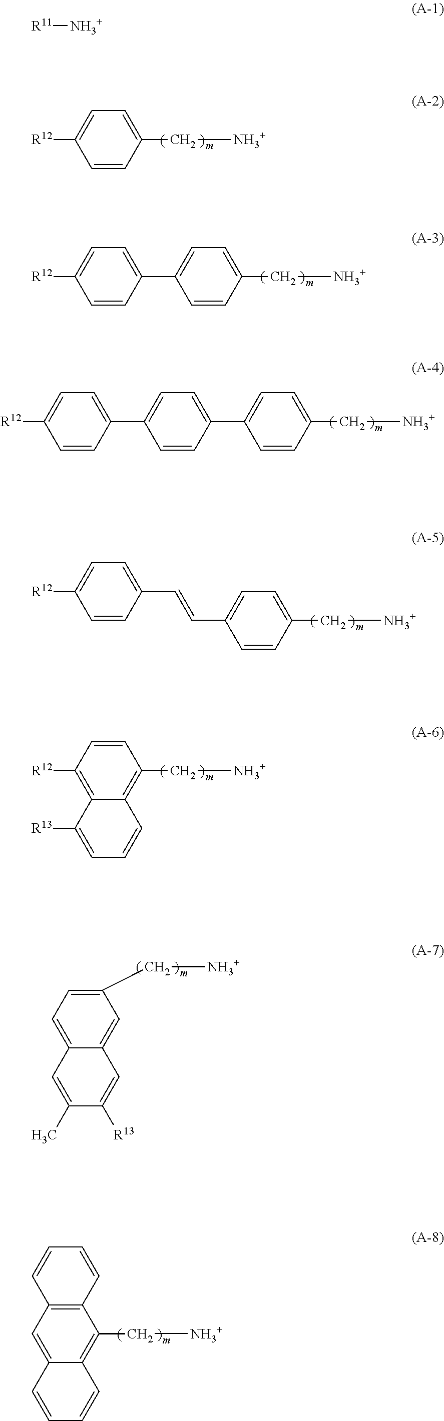 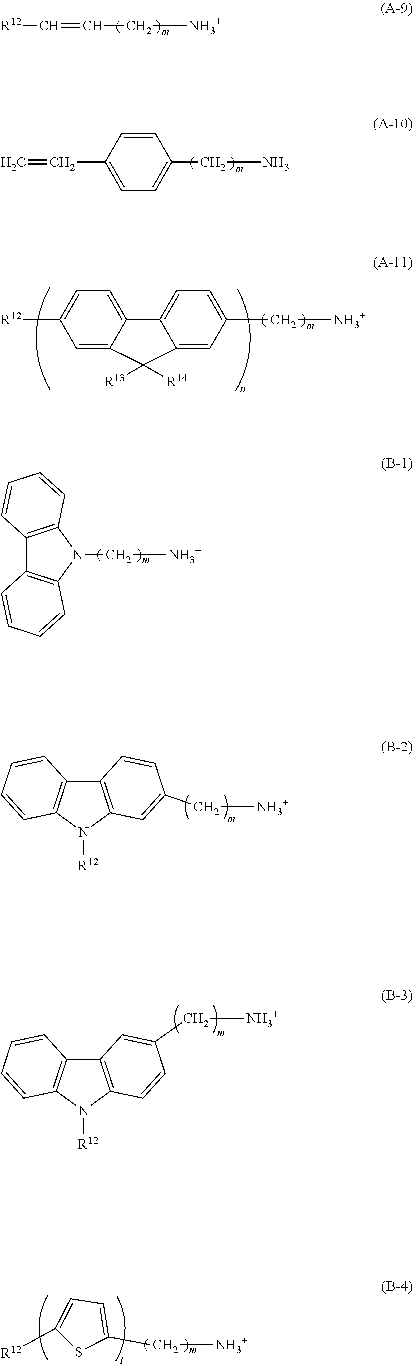 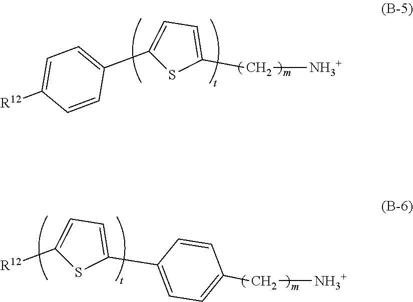
wherein PA is represented by any of General Formulae (C-1), (C-2), and (D) or is branched polyethyleneimine including ammonium cations 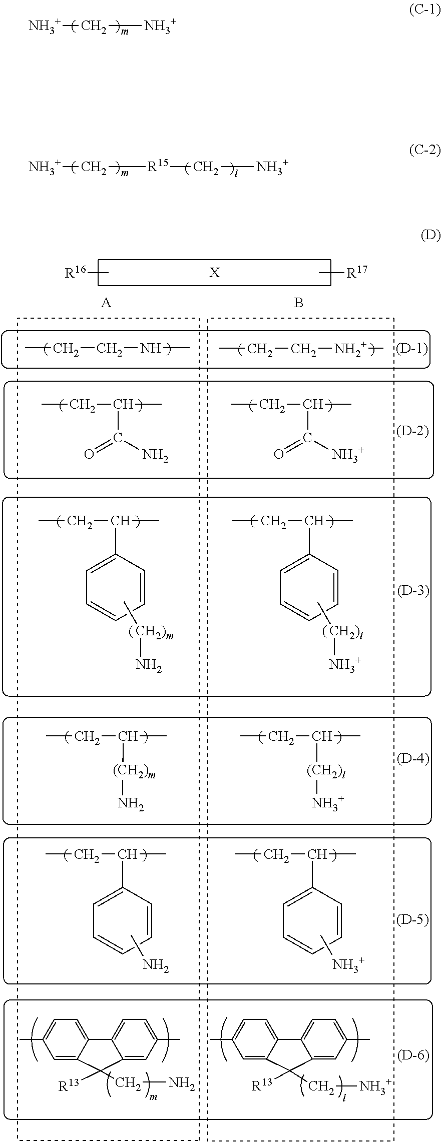
wherein R¹¹ represents an alkyl group having 2 to 18 carbon atoms,
wherein R¹², R¹³, and R¹⁴ represent hydrogen or an alkyl group having 1 to 18 carbon atoms,
wherein R¹⁵ represents any of Structural or General Formulae (R¹⁵-1) to (R¹⁵-14) 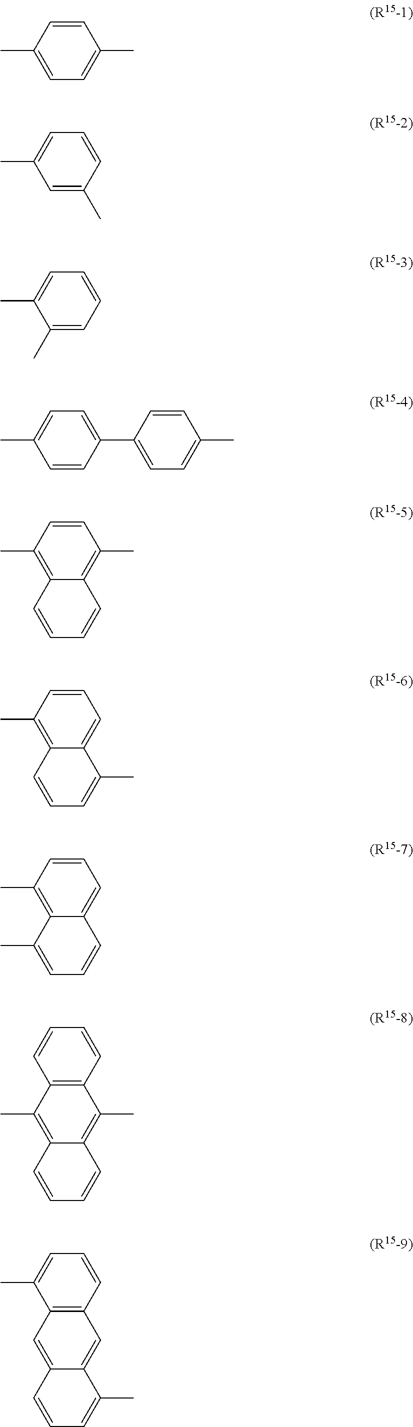 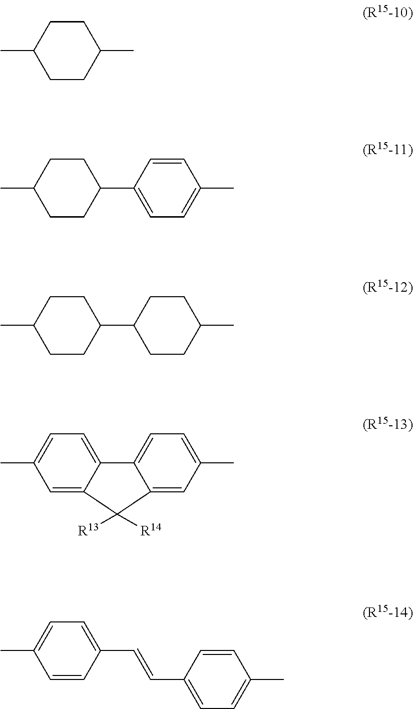
wherein R¹⁶ and R¹⁷ independently represent hydrogen or an alkyl group having 1 to 6 carbon atoms,
wherein X represents a combination of a monomer unit A and a monomer unit B represented by any of General Formulae (D-1) to (D-6), and has a structure including u monomer units A and v monomer units B,
wherein m and/are independently an integer of 0 to 12, and t is an integer of 1 to 18,
wherein u is an integer of 0 to 17,
wherein v is an integer of 1 to 18, and
wherein u+v is an integer of 1 to 18.

14. The light-emitting element according to claim 12, further comprising an electron-injection buffer layer between the second electron-transport layer and the cathode.

15. The light-emitting element according to claim 14, wherein the electron-injection buffer layer comprises an alkali metal or an alkaline earth metal.

16. The light-emitting element according to claim 14, wherein the second electron-transport material interacts with an alkali metal or an alkaline earth metal to form a state which facilitates electron injection from the cathode to the layer comprising the light-emitting substance.

17. The light-emitting element according to claim 12, wherein the second electron-transport material comprises a six-membered heteroaromatic ring including nitrogen.

18. The light-emitting element according to claim 12, wherein the second electron-transport material comprises a 2,2′-bipyridine skeleton.

19. The light-emitting element according to claim 12, wherein the second electron-transport material comprises a phenanthroline derivative.

20. The light-emitting element according to claim 12, wherein the first electron-transport material comprises a condensed aromatic hydrocarbon ring.

21. The light-emitting element according to claim 12, wherein the first electron-transport material comprises an anthracene derivative.

22. The light-emitting element according to claim 12, wherein the metal-halide perovskite material is a particle comprising a longest part being 1 μm or less.

23. The light-emitting element according to claim 12, wherein the metal-halide perovskite material has a layered structure in which a perovskite layer and an organic layer are stacked.
